(19) United States
(12) Patent Application Publication
(10) Pub. No.: US 2022/0415892 A1
(43) Pub. Date: Dec. 29, 2022

(54) STACKED TWO-LEVEL BACKEND MEMORY

(71) Applicant: INTEL CORPORATION, Santa Clara, CA (US)

(72) Inventors: Wilfred Gomes, Portland, OR (US); Abhishek A. Sharma, Hillsboro, OR (US); Conor P. Puls, Portland, OR (US); Mauro J. Kobrinsky, Portland, OR (US); Kevin J. Fischer, Hillsboro, OR (US); Derchang Kau, Cupertino, CA (US); Albert Fazio, Saratoga, CA (US); Tahir Ghani, Portland, OR (US)

(73) Assignee: INTEL CORPORATION, Santa Clara, CA (US)

(21) Appl. No.: 17/358,073

(22) Filed: Jun. 25, 2021

(51) Int. Cl. H01L 27/105

(52) U.S. Cl. CPC H01L 27/1052

(57) ABSTRACT

Integrated circuit (IC) devices with stacked two-level backend memory, and associated systems and methods, are disclosed. An example IC device includes a front end of line (FEOL) layer, including frontend transistors, and a back end of line (BEOL) layer above the FEOL layer. The BEOL layer includes a first memory layer with memory cells of a first type, and a second memory layer with memory cells of a second type. The first memory layer may be between the FEOL layer and the second memory layer, thus forming stacked backend memory. Stacked backend memory architecture may allow significantly increasing density of memory cells in a memory array having a given footprint area, or, conversely, reducing the footprint area of the memory array with a given memory cell density. Implementing two different types of backend memory may advantageously increase functionality and performance of backend memory.

### BACKGROUND

Embedded memory is important to the performance of modern system-on-a-chip (SoC) technology. Low power and high density embedded memory is used in many different computer products and further improvements are always desirable.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a block diagram of an integrated circuit (IC) device with stacked two-level backend memory, according to some embodiments of the present disclosure.

FIG. 2 provides an electric circuit diagram of a one access transistor (1T) and one capacitor (1C) (1T-1C) memory cell, according to some embodiments of the present disclosure.

FIGS. 3A-3B are cross-sectional and plan views, respectively, of an example thin-film transistor (TFT) based memory cell with an access TFT, according to some embodiments of the present disclosure.

FIGS. 4A-4B are cross-sectional views of an example structure of the access TFT in the memory cell of FIGS. 3A-3B, according to some embodiments of the present disclosure.

FIG. 5 provides an electric circuit diagram of an array of 1T-1C memory cells, according to some embodiments of the present disclosure.

FIG. 6A is a perspective view of a cross-point memory array, according to some embodiments of the present disclosure.

FIG. 6B is a schematic illustration of a memory cell of the memory array of FIG. 6A, according to some embodiments of the present disclosure.

FIG. 6C is a plot depicting example characteristic voltages of the selector device and the storage element of the memory cell of FIGS. 6A and 6B, according to some embodiments of the present disclosure.

FIGS. 7A-7B are cross-sectional views of example selector devices for a cross-point memory array, according to some embodiments of the present disclosure.

FIG. 8 is a schematic illustration of a cross-point memory device, according to some embodiments of the present disclosure.

FIG. 9 provides a cross-sectional view of an example IC device with stacked two-level backend memory, according to various embodiments of the present disclosure.

FIG. 10 is a flow diagram of an illustrative method of manufacturing an IC device with stacked two-level backend memory, according to some embodiments of the present disclosure.

FIGS. 11A-11B are top views of a wafer and dies that include stacked two-level backend memory in accordance with any of the embodiments disclosed herein.

FIG. 12 is a cross-sectional side view of one side of an IC device that may include stacked two-level backend memory in accordance with any of the embodiments disclosed herein.

FIG. 13 is a cross-sectional side view of an IC package that may include one or more IC devices with stacked two-level backend memory in accordance with any of the embodiments disclosed herein.

FIG. 14 is a cross-sectional side view of an IC device assembly that may include one or more IC devices with stacked two-level backend memory in accordance with any of the embodiments disclosed herein.

FIG. 15 is a block diagram of an example computing device that may include one or more IC devices with stacked two-level backend memory in accordance with any of the embodiments disclosed herein.

### DETAILED DESCRIPTION

### Overview

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

IC devices with stacked two-level backend memory, and associated systems and methods, are disclosed. An example IC device includes a front end of line (FEOL) layer, including frontend transistors, and a back end of line (BEOL) layer above the FEOL layer. The BEOL layer includes a first memory layer with memory cells of a first type, and a second memory layer with memory cells of a second type. The first memory layer may be between the FEOL layer and the second memory layer. Because the second memory layer is stacked over the first memory layer and the first memory layer is stacked over the FEOL layer, such memory is referred to as “stacked” memory. Because the first and second memory layers are implemented in the BEOL layer, memory implemented in these layers is referred to as “backend” memory. Stacked backend memory architecture as described herein may allow significantly increasing density of memory cells in a memory array having a given footprint area (the footprint area being defined as an area in a plane of the substrate, or a plane parallel to the plane of the substrate, i.e., the x-y plane of an example coordinate system shown in the drawings of the present disclosure), or, conversely, allows significantly reducing the footprint area of the memory array with a given memory cell density. Because two different types of memory are implemented in a BEOL layer of an IC device, such memory is referred to as “two-level” memory. Implementing two different types of backend memory may advantageously increase functionality and performance of backend memory. In further embodiments, more than two different types of backend memory may be implemented in an IC device, but, for simplicity, such IC devices may still be referred to as IC devices with stacked two-level backend memory.

Although descriptions of the present disclosure may refer to logic devices (e.g., implemented using frontend transistors of a FEOL layer) or memory cells provided in a given layer of an IC device, each layer of the IC devices described herein may also include other types of devices besides logic or memory devices described herein. For example, in some embodiments, FEOL layers with logic transistors may also include memory cells and/or BEOL layers with memory cells may also include logic transistors. In general, a FEOL layer may include one or more layers, each including frontend components and/or interconnects, and a BEOL layer may include one or more layers, each including backend components (e.g., backend memory) and/or interconnects.

Various manners of differentiating between different memory types included in an IC device with stacked two-level backend memory can be envisioned, all of which being within the scope of the present disclosure. For example, the first type may be a relatively fast memory such as dynamic random-access memory (DRAM), while the second type may be a relatively slow memory such as cross-point memory or NAND memory, or vice versa. In another example, the first type may be flat memory (also sometimes referred to as a “flat hierarchy memory” or a “linear memory”), while the second type may be hierarchical memory, or vice versa. As known in the art, a flat memory or a linear memory refers to a memory addressing paradigm in which memory may appear to the program as a single contiguous address space, where a processor can directly and linearly address all of the available memory locations without having to resort to memory segmentation or paging schemes. On the other hand, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . , mₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in a BEOL layer of an IC device may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how backend memory in a BEOL layer of an IC device may be arranged.

Some embodiments of the present disclosure may refer to DRAM and, in particular, embedded DRAM (eDRAM), because this type of memory has been introduced in the past to address the limitation in density and standby power of other types or memory. However, embodiments of the present disclosure are equally applicable to backed memory implemented using other technologies. Thus, in general, backend memory described herein may be implemented as DRAM cells, cross-point memory, NAND memory, static random-access memory (SRAM), spin-transfer torque random-access memory (STTRAM) cells, resistive switching memory (e.g., magnetoresistive random-access memory (MRAM) or resistive random-access memory (RRAM)), or any other memory types.

Furthermore, some descriptions may refer to backend memory being TFT-based memory. However, embodiments of the present disclosure are equally applicable to backend memory implemented using layer transfer instead of, or in addition to, TFTs.

In addition, some descriptions may refer to a particular source or drain (S/D) region of a transistor being either a source region or a drain region. However, unless specified otherwise, which region of a transistor is considered to be a source region and which region is considered to be a drain region is not important because, as is common in the field of field-effect transistors (FETs), designations of source and drain are often interchangeable. Therefore, descriptions of some illustrative embodiments of the source and drain regions provided herein are applicable to embodiments where the designation of source and drain regions may be reversed. Unless explained otherwise, in some settings, the terms S/D region, S/D contact, and S/D terminal of a transistor may be used interchangeably, although, in general, the term “S/D contact” is used to refer to an electrically conductive structure for making a contact to a S/D region of a transistor, while the term “S/D terminal” may generally refer to either S/D region or S/D contact of a transistor.

Still further, while some descriptions provided herein may refer to transistors being bottom-gated transistors, embodiments of the present disclosure are not limited to only this design and include transistors of various other architectures, or a mixture of different architectures. For example, in various embodiments, transistors described herein, may include bottom-gated transistors, top-gated transistors, FinFETs, nanowire transistors, nanoribbon transistors, planar transistors, etc., all of which being within the scope of the present disclosure.

In the following detailed description, various aspects of the illustrative implementations will be described using terms commonly employed by those skilled in the art to convey the substance of their work to others skilled in the art. For example, a term “interconnect” may be used to describe any interconnect structure formed of an electrically conductive material for providing electrical connectivity to one or more components associated with an IC or/and between various such components. In general, the term “interconnect” may refer to both conductive lines (or, simply, “lines,” also sometimes referred to as “traces” or “trenches”) and conductive vias (or, simply, “vias”). In general, in context of interconnects, the term “conductive line” may be used to describe an electrically conductive element isolated by an insulator material (e.g., a low-k dielectric material) that is provided within the plane of an IC die. Such lines are typically stacked into several levels, or several layers, of a metallization stack. On the other hand, the term “via” may be used to describe an electrically conductive element that interconnects two or more lines of different levels. To that end, a via may be provided substantially perpendicularly to the plane of an IC die and may interconnect two lines in adjacent levels or two lines in not adjacent levels. A term “metallization stack” may be used to refer to a stack of one or more interconnects for providing connectivity to different circuit components of an IC chip. Sometimes, lines and vias may be referred to as “metal traces” and “metal vias”, respectively, to highlight the fact that these elements include electrically conductive materials such as metals.

In another example, the terms “package” and “IC package” are synonymous, as are the terms “die” and “IC die,” the term “insulating” means “electrically insulating,” the term “conducting” means “electrically conducting,” unless otherwise specified. Although certain elements may be referred to in the singular herein, such elements may include multiple sub-elements. For example, “an electrically conductive material” may include one or more electrically conductive materials. If used, the terms “oxide,” “carbide,” “nitride,” etc. refer to compounds containing, respectively, oxygen, carbon, nitrogen, etc., the term “high-k dielectric” refers to a material having a higher dielectric constant than silicon oxide, while the term “low-k dielectric” refers to a material having a lower dielectric constant than silicon oxide. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. The term “circuit” may be used to describe one or more passive and/or active components that are arranged to cooperate with one another to provide a desired function. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

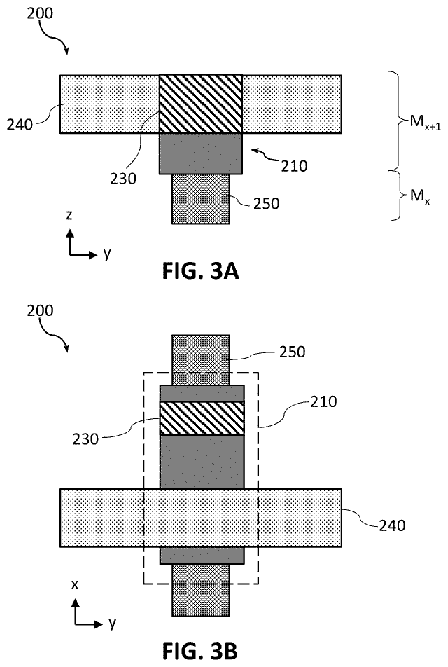

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 3A-3B, such a collection may be referred to herein without the letters, e.g., as “FIG. 3.” In order to not clutter the drawings, sometimes only one instance of a given element is labeled in a drawing with a reference numeral, although other similar elements may be shown.

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Furthermore, although a certain number of a given element may be illustrated in some of the drawings (e.g., a certain number and type of memory layers, a certain number and type of memory cells, or a certain arrangement of interconnects), this is simply for ease of illustration, and more, or less, than that number may be included in the IC devices and related assemblies and packages according to various embodiments of the present disclosure. Still further, various views shown in some of the drawings are intended to show relative arrangements of various elements therein. In other embodiments, various IC devices and related assemblies and packages, or portions thereof, may include other elements or components that are not illustrated (e.g., transistor portions, various further components that may be in electrical contact with any of the illustrated components of the IC devices and related assemblies and packages, etc.). Inspection of layout and mask data and reverse engineering of parts of a device to reconstruct the circuit using e.g., optical microscopy, TEM, or SEM, and/or inspection of a cross-section of a device to detect the shape and the location of various device elements described herein using e.g., physical failure analysis (PFA) would allow determination of presence of one or more IC devices with stacked two-level backend memory as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with stacked two-level backend memory as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

Example IC Devices with Stacked Two-Level Backend Memory

For purposes of illustrating stacked two-level backend memory as described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

Some memory devices may be considered “standalone” devices in that they are included in a chip that does not also include compute logic (where, as used herein, the term “compute logic devices” or simply “compute logic” or “logic devices,” refers to devices, e.g., transistors, for performing computing/processing operations). Other memory devices may be included in a chip along with compute logic and may be referred to as “embedded” memory devices. Using embedded memory to support compute logic may improve performance by bringing the memory and the compute logic closer together and eliminating interfaces that increase latency. Various embodiments of the present disclosure relate to embedded memory arrays, as well as corresponding methods and devices.

DRAM and in particular, embedded DRAM (eDRAM), has been introduced in the past to address the limitation in density and standby power of other types or memory. As an example, a DRAM cell may include a capacitor for storing a bit value, or a memory state (e.g., logical “1” or “0”) of the cell, and an access transistor controlling access to the cell (e.g., access to write information to the cell or access to read information from the cell). Such a memory cell may be referred to as a “1T-1C memory cell,” highlighting the fact that it uses one transistor (i.e., “1T” in the term “1T-1C memory cell”) and one capacitor (i.e., “1C” in the term “1T-1C memory cell”). The capacitor of a 1T-1C memory cell may be coupled to one S/D region of the access transistor (e.g., to the source region of the access transistor), while the other S/D region of the access transistor (e.g., to the drain region) may be coupled to a bit-line (BL), and a gate terminal of the transistor may be coupled to a word-line (WL). Since such a memory cell can be fabricated with as little as a single access transistor, it can provide higher density and lower standby power versus some other types of memory in the same process technology.

Traditionally, memory arrays have been embedded in the same layer with compute logic, in particular, in an upper-most layer of a semiconductor substrate (i.e., in an FEOL layer of an IC device) with transistors for both compute logic and memory arrays implemented as logic-process based transistors (such transistors may be referred to as “frontend transistors” or “FEOL transistors”). Examples of frontend transistors include planar transistors, FinFETs, nanoribbon transistors, nanowire transistors, etc. However, embedding memory arrays in the FEOL layer with compute logic creates several challenges.

One challenge is that, given a usable surface area of a substrate, there are only so many frontend transistors that can be formed in that area, placing a significant limitation on the density of memory cells that may be embedded (e.g., if the memory cells are DRAM cells that also need transistors, to be implemented alongside with the compute logic transistors).

Another challenge is specific to DRAM arrays or other memory technologies that use access transistors in that it relates to the leakage of an access transistor, i.e., current flowing between the source and the drain of a transistor when the transistor is in an “off” state. Since reducing leakage of logic transistors in the scaled technology is difficult, implementing 1T-1C memory in advanced technology nodes (e.g., 10 nanometer (nm), 7 nm, 5 nm, and beyond) can be challenging. In particular, given a certain access transistor leakage, capacitance of the capacitor of a 1T-1C memory cell should be large enough so that sufficient charge can be stored on the capacitor to meet the corresponding refresh times. However, continuous desire to decrease size of electronic components dictates that the macro area of memory arrays continues to decrease, placing limitations on how large the top area (i.e., the footprint) of a given capacitor is allowed to be, which means that capacitors need to be taller in order to have both sufficiently small footprint area and sufficiently large capacitance. As the capacitor dimensions continue to scale, this in turn creates a challenge for etching the openings for forming the capacitors as tall capacitors with small footprint areas require higher aspect ratio openings, something which is not easy to achieve.

Yet another challenge is associated with the use of frontend transistors in 1T-1C memory cells in that it relates to the location of the capacitors such memory cells. Namely, it may be desirable to provide capacitors in metal layers close to their corresponding access transistors. Since frontend transistors provided directly on the semiconductor substrate, the corresponding capacitors of 1T-1C memory cells then have to be embedded in lower metal layers in order to be close enough to the logic access transistors. As the pitches of lower metal layers aggressively scale in advanced technology nodes, embedding the capacitors in the lower metal layers poses significant challenges to the scaling of 1T-1C based memory.

Implementing memory in the backend of an IC device, i.e., in a BEOL layer that may include one or more interconnect layers (also referred to as “metal layers”) may address some of the challenges described above.

Backend memory may be implemented using TFTs as access transistors of the memory cells embedded in the BEOL layer. A TFT is a special kind of a field-effect transistor made by depositing a thin film of an active semiconductor material, as well as a dielectric layer and metallic contacts, over a supporting layer that may be a non-conducting layer and a non-semiconductor layer. At least a portion of the active semiconductor material forms a channel region of the TFT. This is different from conventional, non-TFT, FEOL logic transistors where the semiconductor channel region material of a transistor is typically a part of a semiconductor substrate, e.g., a part of a silicon wafer. Using TFTs as access transistors of memory cells provides several advantages and enables unique architectures that were not possible with conventional, FEOL logic transistors. For example, one advantage is that a TFT may have substantially lower leakage than a logic transistor, allowing to relax the demands on the large capacitance placed on a capacitor of a 1T-1C memory cell. In other words, using a lower leakage TFT in a 1T-1C memory cell allows the memory cell to use a capacitor with lower capacitance and smaller aspect ratio while still meeting the same data retention requirements of other approaches, alleviating the scaling challenges of capacitors.

Additionally, or alternatively, to TFT-based memory, backend memory may be implemented using layer transfer to form access transistors of the memory cells embedded in the BEOL layer. Layer transfer may include epitaxially growing a layer of a highly crystalline semiconductor material on another substrate and then transferring the layer, or a portion thereof, to embed it in the BEOL layer provided over a second substrate. Channel regions of backend transistors then include at least portions of such transferred semiconductor material layer. Performing layer transfer may advantageously allow forming non-planar transistors, such as FinFETs, nanowire transistors, or nanoribbon transistors, in the BEOL layer. In some embodiments, transistors, or portions thereof (e.g., S/D regions) may be formed on the first substrate (i.e., on the substrate on which a layer of a highly crystalline semiconductor material is grown) before the layer transfer takes place, and then a layer with such transistors, or portions thereof, is transferred.

Layer transfer approach for providing backend memory may be particularly suitable for forming access transistors with channel regions formed of substantially single-crystalline semiconductor materials. On the other hand, TFT-based backend memory may be seen as an example of a monolithic integration approach because the semiconductor materials for the channel regions are deposited in a BEOL layer of an IC device, as opposed to being epitaxially grown elsewhere and then transferred, which may be particularly suitable for forming access transistors with channels formed of polycrystalline, polymorphous, or amorphous semiconductor materials, or various other thin-film channel materials. Whether a semiconductor material of a channel region for a given backend device (e.g., a backend transistor) has been provided by monolithic integration approach or by layer transfer can be identified by inspecting grain size of active semiconductor material of the device (e.g., of the semiconductor material of the channel region of a backend transistor). An average grain size of the semiconductor material being between about 0.5 and 1 millimeters (in which case the material may be considered to be polycrystalline) or smaller than about 0.5 millimeter (in which case the material may be considered to be polymorphous) may be indicative of the semiconductor material having been deposited in the BEOL layer of the device (i.e., monolithic integration approach), e.g., to form a TFT. On the other hand, an average grain size of the semiconductor material being equal to or greater than about 1 millimeter (in which case the material may be considered to be a single-crystal material) may be indicative of the semiconductor material having been included in the BEOL layer of the device by layer transfer. The discussions of monolithic integration vs. layer transfer approaches for forming backend memory are equally applicable to backend transistors that are not part of a memory array (e.g., if backend transistors are implemented in an IC device to serve as logic transistors, switches, or for any other purposes or in any other circuits).

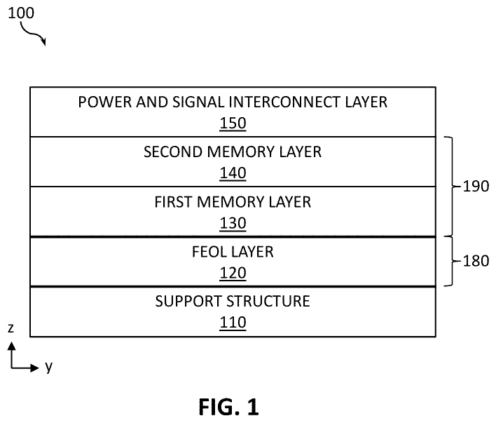

Moving access transistors to the BEOL layer of an advanced complementary metal oxide semiconductor (CMOS) process, either by monolithic integration (e.g., using TFTs) or by layer transfer, means that their corresponding capacitors can be implemented in the upper metal layers with correspondingly thicker interlayer dielectric (ILD) and larger metal pitch to achieve higher capacitance. This eases the integration challenge introduced by embedding the capacitors. Furthermore, when at least some access transistors are implemented as backend transistors, at least portions of different memory cells may be provided in different layers of a BEOL layer above a substrate, thus enabling a stacked architecture of memory arrays. In this context, the term “above” refers to a layer in the BEOL layer being further away from the FEOL layer of an IC device (e.g., the IC device 100 shown in FIG. 1).

FIG. 1 provides a block diagram of an IC device 100 with stacked two-level backend memory, according to some embodiments of the present disclosure. As shown in FIG. 1, in general, the IC device 100 may include a support structure 110, an FEOL layer 120, a first memory layer 130, a second memory layer 140, and a power and signal interconnect layer 150. In various embodiments, each of the layers shown in FIG. 1 may include multiple layers, and, in further embodiments, the IC device 100 may include additional memory layers stacked above the second memory layer 140. Together, the memory layers (e.g., at least the first memory layer 130 and the second memory layer 140, but possibly also additional memory layers not specifically shown in FIG. 1) form a BEOL layer 190, thus the memory implemented in the first and second layers 130, 140 is a stacked backend memory.

In general, implementations of the present disclosure may be formed or carried out on a substrate, such as a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. In some embodiments, the substrate may be non-crystalline. In some embodiments, the substrate may be a printed circuit board (PCB) substrate. Although a few examples of materials from which the substrate may be formed are described here, any material that may serve as a foundation upon which the FEOL devices (e.g., frontend transistors) of the FEOL layer 120 may be built falls within the spirit and scope of the present disclosure.

In some embodiments, the support structure 110 may include a semiconductor substrate as described above. In other embodiments, the support structure 110 may be a support structure of a non-semiconductor material. For example, such a support structure may be provided after the FEOL devices of the FEOL layer 120 (and, possibly, after the stacked two-level backend memory has been implemented in the BEOL 190) have been formed over a semiconductor substrate, after which the semiconductor substrate may be removed (e.g., by flipping the IC device and polishing or grinding the semiconductor substrate to reduce its thickness, e.g., reducing the thickness of the semiconductor substrate until electrical contacts can be made to the FEOL devices of the FEOL layer 120) and, instead a non-semiconductor support structure may be attached (e.g., using a bonding process such as oxide bonding) to provide mechanical stability. In some embodiments, when the support structure 110 is a non-semiconductor support structure, it may be, or may include, any non-semiconductor material that has a dielectric constant lower than that of silicon (Si), e.g., lower than about 11, e.g., or lower than about 10.5. In some such embodiments, the support structure 110 may include, a glass substrate, a glass die, a glass wafer or a glass chip, and/or may include any suitable glass material, since glass has dielectric constants in a range between about 5 and 10.5. Examples of glass materials include silicon oxide materials, possibly doped with elements and compounds such as boron, carbon, aluminum, hafnium oxide, e.g., in doping concentrations of between about 0.01% and 10%. In other embodiments of the support structure 110 being a non-semiconductor support structure, it may be, or include, other solid materials having a dielectric constant lower than that of Si, such as mica. Using a support structure with a dielectric constant lower than that of Si at the back of an IC device (e.g., as shown in FIG. 1) may advantageously decrease various parasitic effects associated with the FEOL/frontend devices of the IC device 100, since such parasitic effects are typically proportional to the dielectric constant of the surrounding medium.

FIG. 1 and some of the other drawings illustrate an embodiment of the IC device 100 where the FEOL layer 120 is between the support structure 110 and the BEOL layer 190. However, although not specifically shown in FIG. 1 and other drawings, in some embodiments, the support structure 110 may be provided over the BEOL layer 190, so that the BEOL layer 190 is between the FEOL layer 120 and the support structure 110. For example, such a support structure may be provided after the FEOL devices of the FEOL layer 120 (and, possibly, after stacked two-level backend memory has been implemented in the BEOL 190) have been formed over a semiconductor substrate, after which the BEOL layer 190, or any layer provided over the BEOL layer 190, may be attached to the support structure 110 (e.g., using a bonding process such as oxide bonding). In some embodiments, a support structure 110 provided at the front of the IC device 100 (i.e., so that the BEOL layer 190 is between the FEOL layer 120 and the support structure 110) may include any of the semiconductor or non-semiconductor materials described above. Using a support structure 110 provided at the front of the IC device 100 in the form of a support structure with a dielectric constant lower than that of Si (e.g., any of the glass materials, mica, etc., described above), may advantageously decrease various parasitic effects associated with the BEOL/backend devices of the IC device 100 and/or various parasitic effects associated with the power and signal interconnects that may be implemented at the front of the IC device 100 (e.g., if such a support structure is coupled to a power and signal interconnect layer 150 as shown in FIG. 1).

A thickness of the support structure 110 may be of any value for the support structure 110 to provide mechanical stability for the IC device 100 and, possibly, to support inclusion of various devices for further reducing the parasitic effects in the IC device. In some embodiments, the support structure 110 may have a thickness between about 0.2 micrometer (micron) and 1000 micron, e.g., between about 0.5 and 5 micron, or between about 1 and 3 micron. Although a few examples of materials from which the support structure 110 may be formed are described here, any material that may serve as a foundation upon which an IC device that includes stacked two-level backend memory as described herein may be provided falls within the spirit and scope of the present disclosure.

The first and second memory layers 130, 140 may, together, be seen as forming stacked two-level backend memory of the BEOL layer 190. As such, the memory array of the BEOL layer 190 may include TFTs or transistors formed by layer transfer (e.g., access transistors of memory cells as described herein), storage elements (e.g., capacitors), as well as WLs (e.g., row selectors), BLs (e.g., column selectors), and possibly other control lines, making up backend memory cells. In some embodiments, the memory arrays of the BEOL layer 190 may include more than two memory layers stacked in different layers above one another.

On the other hand, the FEOL layer 120 may be a compute logic layer in that it may include various logic layers, circuits, and devices (e.g., logic transistors, e.g., frontend transistors) to drive and control a logic IC. For example, the logic devices of the compute logic layer 120 may form a memory peripheral circuit 180 to control (e.g., access (read/write), store, refresh) the backend memory of the BEOL layer 190.

In some embodiments, the FEOL layer 120 may be provided in a FEOL and in one or more lowest BEOL sub-layers of the BEOL Layer 190 (i.e., in one or more BEOL sub-layers which are closest to the substrate over which the frontend devices of the FEOL layer 120 were built), while the first memory layer 130 and the second memory layer 140 may be seen as provided in respective higher BEOL sub-layers. Various sub-layers of the BEOL layer 190 may be (or may include) metal layers (also interchangeably referred to as “interconnect layers”) of a metallization stack, as known in the art. Various metal layers of the BEOL layer 190 may be used to interconnect the various inputs and outputs of the frontend devices in the FEOL layer 120 and/or of the memory cells in the memory layers 130, 140. Generally speaking, each of the metal layers of the BEOL layer 190 may include interconnect structures such as conductive vias and conductive lines, as well as other components, such as memory cells. While referred to as “metal” layers, various layers of the BEOL layer 190 may include only certain patterns of conductive metals, e.g., copper (Cu), aluminum (Al), tungsten (W), or cobalt (Co), or metal alloys, or more generally, patterns of one or more electrically conductive materials, formed in an insulating medium such as an ILD. The insulating medium may include any suitable ILD materials such as silicon oxide, carbon-doped silicon oxide, silicon carbide, silicon nitride, aluminum oxide, and/or silicon oxynitride.

In other embodiments of the IC device 100, compute logic devices may be provided in a layer above the memory layers 130, 140, in between memory layers 130, 140, or combined with the memory layers 130, 140.

The power and signal interconnect layer 150, also shown in FIG. 1, may include one or more interconnects configured to provide power and/or signals to/from various components of the IC device 100 (e.g., to the devices in the FEOL layer 120 and/or to the memory cells of the stacked two-level backend memory in the BEOL layer 190). Although the power and signal interconnect layer 150 is shown in FIG. 1 as being over the BEOL layer 190 (i.e., at the front of the IC device 100, so that the BEOL layer 190 is between the FEOL layer 120 and the power and signal interconnect layer 150), in other embodiments of the IC device 100, the power and signal interconnect layer 150 may be implemented at the back side of the IC device 100, so that the FEOL layer 120 is between the power and signal interconnect layer 150 and the BEOL layer 190. In still further embodiments of the IC device 100, some portions of the power and signal interconnect layer 150 may be implemented at the back side of the IC device 100 while other portions of the power and signal interconnect layer 150 may be implemented at the front side of the IC device 100.

The illustration of FIG. 1 is intended to provide a general orientation and arrangement of various layers with respect to one another, and, unless specified otherwise in the present disclosure, includes embodiments of the IC device 100 where portions of elements described with respect to one of the layers shown in FIG. 1 may extend into one or more, or be present in, other layers. For example, power and signal interconnects for the various components of the IC device 100 may be present in any of the layers shown in FIG. 1, although not specifically illustrated in FIG. 1.

### Example Memory Arrays for an IC Device with Stacked Two-Level Backend Memory

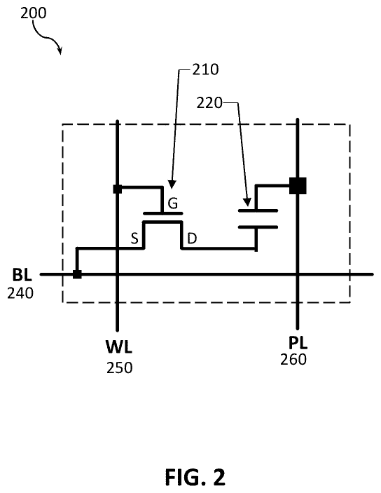

In some embodiments, any of the memory layers implemented in the BEOL layer 190 of the IC device 100 (e.g., the first memory layer 130 or the second memory layer 140) may include a DRAM array with 1T-1C memory cells. DRAM implementations are described with reference to FIGS. 2-5.

FIG. 2 provides an electric circuit diagram of an 1T-1C memory cell 200, according to some embodiments of the present disclosure. As shown, the 1T-1C cell 200 may include an access transistor 210 and a capacitor 220. The access transistor 210 has a gate terminal, a source terminal, and a drain terminal, indicated in the example of FIG. 2 as terminals G, S, and D, respectively. In the following, the terms “terminal” and “electrode/contact” may be used interchangeably. Furthermore, for S/D terminals, the terms “terminal” and “region” may be used interchangeably.

As shown in FIG. 2, in the 1T-1C cell 200, the gate terminal of the access transistor 210 may be coupled to a WL 250, one of the S/D terminals of the access transistor 210 may be coupled to a BL 240, and the other one of the S/D terminals of the access transistor 210 may be coupled to a first electrode of the capacitor 220. As also shown in FIG. 2, the other electrode of the capacitor 220 may be coupled to a capacitor plate-line (PL) 260 (also sometimes referred to as a “select-line” (SL)). As is known in the art, WL, BL, and PL may be used together to read and program the capacitor 220. Each of the BL 240, the WL 250, and the PL 260, as well as intermediate elements coupling these lines to various terminals described herein, may be formed of any suitable electrically conductive material, which may include an alloy or a stack of multiple electrically conductive materials. In various embodiments, such electrically conductive materials may include one or more metals or metal alloys, with metals such as ruthenium, palladium, platinum, cobalt, nickel, hafnium, zirconium, titanium, tantalum, and aluminum, and/or one or more oxides or carbides of such metals or metal alloys.

In some embodiments, the access transistor 210 may be a TFT. In other embodiments, the access transistor 210 may be not a TFT, e.g., a transistor formed on a crystalline semiconductor material provided in the backend of an IC device using layer transfer. For example, in some such embodiments, the access transistor 210 may be a Fin FET, a nanowire, or a nanoribbon transistor.

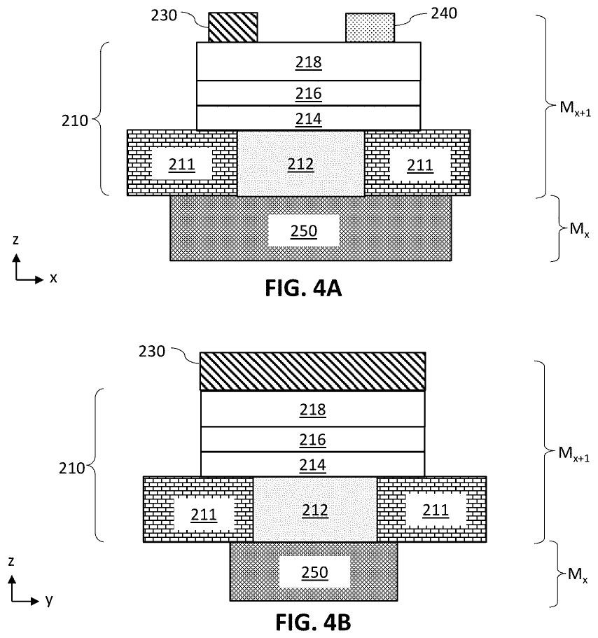

FIGS. 3A-3B are cross-sectional (y-z plane) and plan (y-x plane) views, respectively, of an example access transistor 210 implemented as a TFT in a TFT-based memory cell 200, according to some embodiments of the present disclosure. For example, the access TFT 210 illustrated in FIGS. 3A-3B may be the access transistor 210 of FIG. 2, and the memory cell 200 illustrated in FIGS. 3A-3B may be the memory cell 200 of FIG. 2. FIGS. 4A-4B are cross-sectional views (x-z and y-z planes) of an example structure of the access TFT 210 in the TFT-based memory cell 200 of FIGS. 3A-3B, according to some embodiments of the present disclosure. The memory cell 200 shown in FIGS. 2-4 is an example of memory cells of a first type (e.g., DRAM) that may be implemented to realize a given memory layer of an IC device with stacked two-level backend memory as described herein, e.g., of the IC device 100 as described herein. In some embodiments of the IC device 100 as described herein, multiple memory cells 200 (as well as multiple memory cells of other types) may be arranged in a stacked architecture, i.e., when different memory cells such as the one shown in FIGS. 2-4 are stacked in different interconnect layers of the BEOL layer 190.

As shown in FIG. 3, the TFT-based memory cell 200 may include a WL 250 (which may be an example of the WL 250 of FIG. 2) to supply a gate signal. As also shown in FIG. 3, the TFT-based memory cell 200 may further include an access TFT 210 that includes a channel layer and is configured to control transfer of a memory state of the memory cell between a first region and a second region of the channel layer in response to the gate signal (channel layer and first and second regions described in greater detail below, e.g., with reference to FIG. 4). In some embodiments, the access TFT 210 may be provided above the WL 250 coupled to the memory cell 200. As also shown in FIG. 3, the memory cell 200 may further include a BL 240 to transfer the memory state and coupled to the first region of the channel layer of the access TFT 210, and a storage node 230 coupled to the second region of the channel layer of the access TFT 210. Although not specifically shown in FIG. 3, the memory cell 200 further includes a capacitor such as the capacitor 220 of FIG. 2, e.g., a metal-insulator-metal (MIM) capacitor coupled to the storage node 230 and configured to store the memory state of the memory cell 200.

Turning to the details of FIG. 3, the access TFT 210 in the memory cell 200 may be coupled to or controlled by WL 250, which, in some embodiments, may serve as the gate of the access TFT 210. A BL 240 (which may be an example of the BL 240 of FIG. 2) may be coupled to one of the S/D regions of the access TFT 210 and a storage node 230 may be coupled to the other one of the S/D regions of the access TFT 210. In some embodiments, the BL 240 may serve as a first S/D contact (i.e., an electrically conductive structure for making a contact to a first S/D region of a transistor) and the storage node 230 may serve as the second S/D contact (i.e., an electrically conductive structure for making a contact to a second S/D region of a transistor) of the access TFT 210. The BL 240 may be connected to a sense amplifier and a BL driver which may, e.g., be provided in a memory peripheral circuit associated with a memory array that includes the memory cell 200. As shown in FIG. 3A, in some embodiments, for a given memory cell 200, the WL 250 may be formed in a metal layer Mx (where x is an integer indicating a specific layer) of the BEOL layer 190, while the access TFT 210, the storage node 230, and the BL 240 may be formed in a metal layer Mx+1 of the BEOL layer 190, i.e., the metal layer above the metal layer Mx, e.g., directly above the metal layer Mx (as illustrated in FIGS. 3 and 4). A capacitor of the memory cell 200 may then be formed in a metal layer Mx+2 of the BEOL layer 190, e.g., directly above the metal layer Mx+1.

FIGS. 4A-4B illustrate further details of the access TFT 210. As shown in FIGS. 4A-4B, in some embodiments, the access TFT 210 may be provided substantially above the WL 250. In some embodiments, the access TFT 210 may be a bottom-gated TFT in that its gate stack comprising a gate dielectric 216 and a gate electrode 214 may be provided below its channel layer/region (also referred to as “active layer”) 218, e.g., between the channel layer 218 and the WL 250, and the channel layer 218 may be between the gate stack and the BL 240 forming one of the S/D terminals, e.g., the drain terminal, of the access TFT 210 and the storage node 230 forming another one of the S/D terminals, e.g., the source terminal, of the access TFT 210 (again, in other embodiments, this example designation of S/D terminals may be reversed).

The channel layer 218 may be composed of semiconductor material systems including, for example, N-type or P-type materials systems. In some embodiments, the channel layer 218 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the channel layer 218 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In particular, the channel layer 218 may be formed of a thin-film material. Some such materials may be deposited at relatively low temperatures, which allows depositing them within the thermal budgets imposed on back end fabrication to avoid damaging the frontend components such as the logic devices of the FEOL layer 120 of the IC device 100. In some embodiments, the channel layer 218 may have a thickness between about 5 and 75 nanometers, including all values and ranges therein.

The S/D electrodes of the access TFT 210, shown in various figures as provided by the corresponding BL 240 and the storage node 230, respectively, may include any suitable electrically conductive material, alloy, or a stack of multiple electrically conductive materials. In some embodiments, the S/D electrodes of the access TFT 210 may include one or more metals or metal alloys, with metals e.g., copper, ruthenium, palladium, platinum, cobalt, nickel, hafnium, zirconium, titanium, tantalum, and aluminum, tantalum nitride, tungsten, doped silicon, doped germanium, or alloys and mixtures of these. In some embodiments, the S/D electrodes of the access TFT 210 may include one or more electrically conductive alloys, oxides, or carbides of one or more metals. In some embodiments, the S/D electrodes of the access TFT 210 may include a doped semiconductor, such as silicon or another semiconductor doped with an N-type dopant or a P-type dopant. Metals may provide higher conductivity, while doped semiconductors may be easier to pattern during fabrication. In some embodiments, the S/D electrodes of the access TFT 210 may have a thickness (i.e., dimension measured along the z-axis of the example coordinate system shown in the present drawings) between about 2 nanometers and 1000 nanometers, preferably between about 2 nanometers and 100 nanometers.

A gate dielectric 216 may laterally surround the channel layer 218, and the gate electrode 214 may laterally surround the gate dielectric 216 such that the gate dielectric 216 is disposed between the gate electrode 214 and the channel layer 218. In various embodiments, the gate dielectric 216 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric 216 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric 216 during manufacture of the access TFT 210 to improve the quality of the gate dielectric 216. In some embodiments, the gate dielectric 216 may have a thickness between about 0.5 nanometers and 3 nanometers, including all values and ranges therein, e.g., between about 1 and 3 nanometers, or between about 1 and 2 nanometers.

In some embodiments, the gate dielectric 216 may be a multilayer gate dielectric, e.g., it may include any of the high-k dielectric materials in one layer and a layer of IGZO. In some embodiments, the gate stack (i.e., a combination of the gate dielectric 216 and the gate electrode 214) may be arranged so that the IGZO is disposed between the high-k dielectric and the channel layer 218. In such embodiments, the IGZO may be in contact with the channel layer 218, and may provide the interface between the channel layer 218 and the remainder of the multilayer gate dielectric 216. The IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10).

The gate electrode 214 may include at least one P-type work function metal or N-type work function metal, depending on whether the access TFT 210 is a P-type metal oxide semiconductor (PMOS) transistor or an N-type metal oxide semiconductor (NMOS) transistor. For a PMOS transistor, metals that may be used for the gate electrode 214 may include, but are not limited to, ruthenium, palladium, platinum, cobalt, nickel, and conductive metal oxides (e.g., ruthenium oxide). For an NMOS transistor, metals that may be used for the gate electrode 214 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 214 may include a stack of two or more metal layers, where one or more metal layers are work function metal layers and at least one metal layer is a fill metal layer. Further metal layers may be included for other purposes, such as to act as a diffusion barrier layer, described below.

FIGS. 4A-4B further illustrate that the bottom-gated access TFT 210 may further, optionally, include layers such as a diffusion barrier layer 212, which may be surrounded by a layer of etch-resistant material (e.g., an etch-stop layer 211). In some embodiments, the diffusion barrier 212 may be a metal- or copper-diffusion barrier (e.g., a conductive material to reduce or prevent the diffusion of metal or copper from WL 250 into the gate electrode 214 while still maintaining an electrical connection between the WL 250 and the gate electrode 214) on the WL 250 such as TaN, tantalum (Ta), titanium zirconium nitride (e.g., TiXZr1-XN, such as X=0.53), titanium nitride (e.g., TiN), titanium tungsten (TiW), combination (such as a stack structure of TaN on Ta), or the like. For instance, the diffusion barrier 212 can include a single- or multilayer structure including a compound of tantalum (Ta) and nitrogen (n), such as TaN or a layer of TaN on a layer of Ta. In some embodiments, a layer of an etch-resistant material (e.g., the etch-stop 211) such as silicon nitride or silicon carbide may be formed over the WL 250 with vias for a metal (or copper) diffusion barrier film 212 such as TaN or a TaN/Ta stack. The gate electrode 214 can be a conductive material on the diffusion barrier 212, such as metal, conductive metal oxide or nitride, or the like. For example, in one embodiment, the gate electrode 214 may be titanium nitride (TiN). In another embodiment, the gate electrode 214 may be tungsten (W).

The channel layer 218 can be in contact with the BL 240 (e.g., at a first S/D region of the channel layer 218, e.g., a drain region) and with the storage node 230 (e.g., at a second S/D region of the channel layer 218, e.g., a source region, with a semiconducting channel region of the access TFT 210 being between the first S/D region and the second S/D region). In some embodiments, such a channel region may include only majority carriers in the thin film. Accordingly, the channel layer 218 may require a relatively high bias (as e.g., supplied by the WL 250, diffusion barrier film 212, and gate electrode 214) to activate.

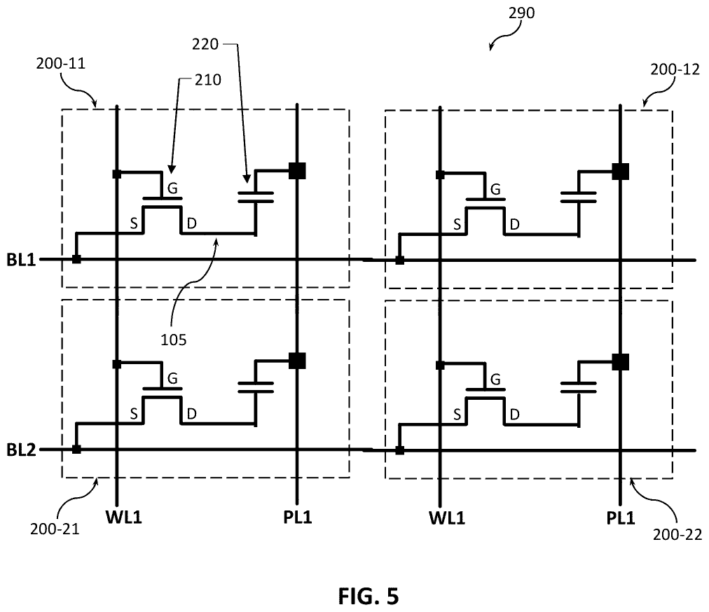

FIG. 5 provides an electric circuit diagram of an array 290 of 1T-1C memory cells 200, according to some embodiments of the present disclosure. Each 1T-1C memory cell 200 as described herein is illustrated in FIG. 5 to be within a dashed box labeled 200-11, 200-12, 200-21, and 200-22. While only four such memory cells are shown in FIG. 5, in other embodiments, the array 290 may, and typically would, include many more memory cells. Furthermore, in other embodiments, the 1T-1C memory cells as described herein may be arranged in arrays in other manners as known in the art, all of which being within the scope of the present disclosure. The array 290 may be included in the BEOL layer 190 of the IC device 100 as described herein, e.g., in the first memory layer 130, and/or in any other memory layers that may be present in the BEOL layer 190 of the IC device 100.

FIG. 5 illustrates that, in some embodiments, a single BL can be shared among multiple memory cells 200 in a column, and that WL and PL can be shared among multiple memory cells 200 in a row. As is conventionally used in context of memory, the terms “row” and “column” do not reflect the, respectively, horizontal and vertical orientation on a page of a drawing illustrating a memory array but, instead, reflect on how individual memory cells are addressed. Namely, memory cells 200 sharing a single BL are said to be in the same column, while memory cells sharing a single WL are said to be on the same row. Thus, in FIG. 5, the horizontal lines refer to columns while vertical lines refer to rows. Different instances of each line (BL, WL, and PL) are indicated in FIG. 5 with different reference numerals, e.g., BL1 and BL2 are the two different instances of the BL as described herein. The same reference numeral on the different lines WL and PL indicates that those lines are used to address/control the memory cells in a single row. For example, WL1 and PL1 are used to address/control the memory cells 200 in row 1 (e.g., the memory cells 200-11 and 200-21, shown in the example of FIG. 5), while WL2 and PL2 are used to address/control the memory cells 200 in row 2 (e.g., the memory cells 200-12 and 200-22, shown in the example of FIG. 5), and so on. The same reference numeral on the different lines BL indicates that those lines are used to address/control the memory cells in a single column. For example, BL1 is used to address/control the memory cells 200 in column 1 (e.g., the memory cells 200-11 and 200-12, shown in the example of FIG. 5), while BL is used to address/control the memory cells 200 in column 2 (e.g., the memory cells 200-21 and 200-22, shown in the example of FIG. 5), and so on. Each memory cell 200 may then be addressed by using the BL corresponding to the column of the cell and by using the WL and PL corresponding to the row of the cell. For example, the memory cell 200-11 is controlled by BL1, WL1, and PL1, the memory cell 200-12 is controlled by BL1, WL2, and PL2, and so on.

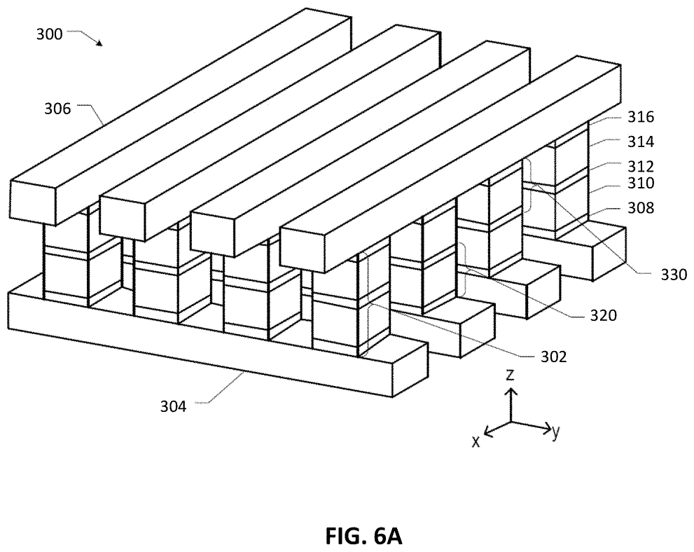

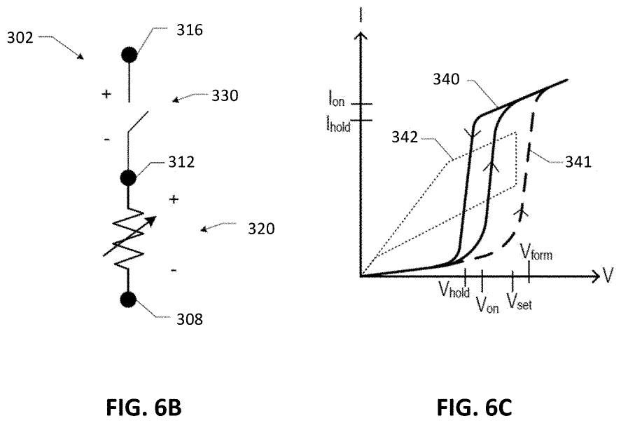

The 1T-1C memory cells described above are examples of memory cells with a 3-terminal device (i.e., the access transistor having gate, source, and drain terminals) configured to control access to a storage element of a memory cell (i.e., the capacitor, for the 1T-1C memory cell). Some other types of memory arrays may implement 2-terminal access devices configured to control access to respective storage elements, e.g., selector devices configured to control access to storage elements of cross-point memory arrays. Such memory arrays provide another example of any of the memory layers that may be implemented in the BEOL layer 190 of the IC device 100 (e.g., the first memory layer 130 or the second memory layer 140). Cross-point memory array implementations are described with reference to FIGS. 6-8.

FIG. 6A is a perspective view of a cross-point memory array 300, according to some embodiments of the present disclosure. The memory array 300 may be a cross-point array including memory cells 302 located at the intersections of conductive lines 304 and conductive lines 306. In some embodiments, the conductive lines 304 may be WLs and the conductive lines 306 may be BLs, for example; for ease of discussion, this terminology may be used herein to refer to the conductive lines 304 and the conductive lines 306. In the embodiment illustrated in FIG. 6A, the WLs 304 may be parallel to each other and may be arranged perpendicularly to the BLs 306 (which themselves may be parallel to each other), but any other suitable arrangement may be used. The WLs 304 and/or the BLs 306 may be formed of any suitable conductive material, such as a metal (e.g., tungsten, copper, titanium, or aluminum). In some embodiments, the memory array 300 depicted in FIG. 6A may be a portion (e.g., a level) of a 3D array in which other memory arrays like the memory array 300 of FIG. 6A are located at different levels (e.g., above or below the memory array 300).

Each memory cell 302 may include a storage element 320 coupled in series with an associated selector device 330.

Generally, a storage element 320 may be programmed to a target data state (e.g., corresponding to a particular resistance state) by applying an electric field or energy (e.g., positive or negative voltage or current pulses) to the storage element 320 for a particular duration. In some embodiments, a storage element 320 may include a memory material 310 disposed between a pair of electrodes 308 and 312. The storage element 320 may be, for example, a resistive storage element (also referred to herein as a “resistive switch”) that, during operation, switches between two different nonvolatile states: a high resistance state (HRS) and a low resistance state (LRS). The state of a resistive storage element may be used to represent a data bit (e.g., logical “1” for HRS and logical “0” for LRS, or vice versa). A resistive storage element may have a voltage threshold beyond which the resistive storage element is in the LRS; driving a resistive storage element into the LRS may be referred to as SET (with an associated SET threshold voltage). Similarly, a resistive storage element may have a voltage threshold beyond which the resistive storage element is in the HRS; driving a resistive storage element into the HRS may be referred to as RESET (with an associated RESET threshold voltage).

The storage element 320 may be, for example, a RRAM device; in such embodiments, the memory material 310 may include an oxygen exchange layer (e.g., hafnium) and an oxide layer, as known in the art. The storage element 320 may be, for example, a metal filament memory device (e.g., a conductive bridging random-access memory (CBRAM) device); in such embodiments, the memory material 310 may include a solid electrolyte, one of the electrodes 308 and 312 may be an electrochemically active material (e.g., silver or copper), and the other of the electrodes 308 and 312 may be an inert material (e.g., an inert metal), as known in the art. A chemical barrier layer (e.g., tantalum, tantalum nitride, or tungsten) may be disposed between the electrochemically active electrode and the solid electrolyte to mitigate diffusion of the electrochemically active material into the solid electrolyte, in some such embodiments. In some embodiments, the storage element 320 may be a phase change memory (PCM) device; in such embodiments, the memory material 310 may include a chalcogenide or other phase change memory material. In some embodiments, the storage element 320 may be a MRAM device; in such embodiments, the electrodes 308 and 312 may be magnetic (e.g., ferromagnetic), and the memory material 310 may be a thin tunnel barrier material. As known in the art, MRAM devices may operate on the principle of tunnel magnetoresistance between two magnetic layers (the electrodes 308 and 312) separated by a tunnel junction (the memory material 310). An MRAM device may have two stable states: when the magnetic moments of the two magnetic layers are aligned parallel to each other, an MRAM device may be in the LRS, and when aligned antiparallel, an MRAM device may be in the HRS.

Generally, a selector device 330 is a device exhibiting a volatile change in resistance between two terminals. In an off state, a selector device 330 may exhibit high resistance; in an on state, a selector device may exhibit low resistance. The selector device 330 may be a device (with two or more terminals) that may act as a bipolar switch, controlling the flow of current through the storage element 320. In some embodiments, the selector device 330 may include a selector material 314 disposed between a pair of electrodes 312 and 316. Note that, in the embodiment illustrated in FIG. 6A, the electrode 312 of the selector device 330 is “shared” with the storage element 320 in that the electrode 312 acts as an electrode for the selector device 330 and for the storage element 320. In other embodiments of the memory cell 302, the selector device 330 may not share any electrodes with the storage element 320. During manufacture of the memory cell 302, the selector device 330 may be fabricated before or after the storage element 320 is fabricated. Various embodiments of the selector device 330 are discussed in detail below.

As illustrated in the schematic view in FIG. 6B of the memory cell 302, when the selector device 330 is in a conductive (i.e., low resistance) state, the “switch” may be closed; when the selector device 330 is in a non-conductive (i.e., high resistance) state, the “switch” may be open. The state of the selector device 330 may change in response to the voltage applied across the selector device 330. FIG. 6C illustrates example electrical characteristics of an example selector device 330 and an example storage element 320 when positive voltages are applied. The I-V characteristic 340 represents behavior of an example selector device 330, and the I-V characteristic 342 represents behavior of an example storage element 320.

As illustrated in FIG. 6C, the selector device 330 may be in a HRS (an “off state”) when the voltage across the selector device 330 increases from zero to the threshold voltage Von. When the voltage across the selector device 330 reaches and exceeds the threshold voltage Von (and an associated on stage current Ion), the selector device 330 may enter a LRS (an “on state”) and may conduct current of a positive polarity. When the voltage across the selector device 330 is decreased from the threshold voltage Von, the selector device 330 may remain in the on stage until a holding voltage Vhold (and an associated holding current (hold) is reached. When the voltage across the selector device decreases to and beyond the holding voltage Vhold, the selector device 330 may enter the off state again. In some embodiments, the selector device 330 may have a threshold voltage Von between 0.4 volts and 2.5 volts, or 1 volt or less. In some embodiments, the selector device 330 may have an on stage current Ion that is greater than or equal to 0.5 megaamperes per square centimeter. In some embodiments, the selector device 330 may have a holding voltage Vhold between 0.1 volts and 2.5 volts (e.g., between 0.1 volts and 1 volt for embedded applications, and between 0.5 volts and 2 volts for standalone applications).

Note that the holding voltage Vhold may be less than the threshold voltage Von, as illustrated in FIG. 6C. In some embodiments, it may be desirable for the holding voltage Vhold to be approximately the same, as or close to, the threshold voltage Von. In other embodiments, it may be desirable for the holding voltage Vhold to be less than the threshold voltage Von. For example, when the holding voltage Vhold is less than the threshold voltage Von, the voltage across an “on” selector device 330 may be decreased from the threshold voltage Von and the selector device 330 may remain in the on state; this may reduce the power required to keep the selector device 330 on (e.g., during a read operation of the associated storage element 320), and thus may improve power efficiency. The materials used in the electrodes 312/316 of the selector device 330 may allow tuning of the holding voltage Vhold and/or the threshold voltage Von, as discussed in further detail below.

Some selector devices 330 may require or benefit from the application of an initial formation voltage Vform that is larger than the threshold voltage Von when the selector device is first used; FIG. 6C includes a curve 341 illustrating an example initial formation phase. This initial formation phase (sometimes referred to as “first fire”) may “break down” the selector material 314 (e.g., by introducing some of the material of the electrodes 312 and 316 into the selector material 314, or creating regions of inhomogeneous material composition in the selector material 314) so as to allow subsequent on/off behavior as described above.

As noted above, FIG. 6C also depicts an example I-V characteristic 342 for a storage element 320 (e.g., an RRAM device) with a SET threshold voltage Vset. The SET threshold voltage Vset may be greater than the threshold voltage Von for the selector device 330.

In some embodiments, material compositions of the electrodes 316 of selector devices 330 may be chosen, among other factors, to achieve a desired holding voltage Vhold and/or a desired threshold voltage Von. The holding voltage Vhold may contribute to setting the peak power of a selector device 330 (e.g., reducing Vhold may reduce the power dissipated by the selector device 330), and thus it may be advantageous to engineer a selector device 330 to achieve a desired peak power to achieve a desired power consumption during switching. Some of these selector devices 330 may advantageously exhibit decreased threshold voltages Von relative to conventional selector devices, resulting in improved performance and decreased power consumption. A selector device 330 with a lower threshold voltage Von may be turned on and off with lower applied voltages, and thus may enable new low power applications (e.g., embedded electronics, or integrated circuits in other low power environments). Additionally, achieving a desired holding voltage Vhold for a selector device 330 may also improve power efficiency and behavior.

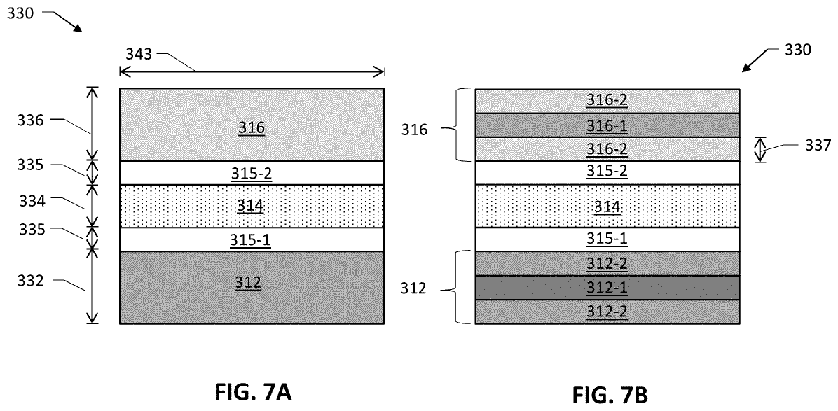

The selector devices 330 disclosed herein, and the associated memory cells 302, may take any of a number of forms. For example, FIGS. 7A and 7B are cross-sectional views of different embodiments of a selector device 330, in accordance with various embodiments. The selector devices 330 of FIG. 7 may include an electrode 316, an electrode 312, and a selector material 314 between the electrodes 316 and 312. During operation, one of the electrodes 312/316 of the selector device 330 may be at a more positive potential than the other electrode; this “more positive” electrode of the electrodes 312/316 may be referred to as the “injecting” electrode, while the “more negative” electrode of the electrodes 312/316 may be referred to as the “non-injecting” electrode.

FIG. 7 also illustrates a getter layer 315-1 between the selector material 314 and the electrode 312, and a getter layer 315-2 between the selector material 314 and the electrode 316. A getter layer 315 may serve to, among other things, trap unwanted impurities in the selector material 314. In some embodiments, a getter layer 315 may include a material having a relatively low work function (e.g., less than 4.5 electron volts, as discussed below) and a relatively high oxide formation energy. In some embodiments, a getter layer 315 may include tantalum (e.g., tantalum nitride), titanium (e.g., titanium nitride), hafnium, aluminum, or chromium. Various embodiments of the selector devices 330 disclosed herein may include fewer getter layers 315 than are depicted in FIG. 7; in some embodiments, the selector device 330 may include a getter layer 315-1 but not a getter layer 315-2, or may include a getter layer 315-2 but not a getter layer 315-2, or may not include any getter layers 315. For example, when an electrode 312/316 includes a relatively low reactivity material (such as copper or tungsten), the adjacent getter layer 315 may be omitted.

The electrodes 312 and 316 may be formed of any suitable electrically conductive material. In some embodiments, the electrodes 312 and 316 may include tantalum, platinum, hafnium, cobalt, indium, iridium, copper, tungsten, ruthenium, palladium, and/or carbon. The electrodes 312 and 316 may be composed of pure forms of these elements, combinations of these elements, or combinations of these elements and other elements, in some embodiments. For example, in some embodiments, the electrode 312 and/or the electrode 316 may include a conductive nitride (e.g., tantalum nitride or titanium nitride). In some embodiments, the material compositions of the electrodes 312 and 316 may be the same, while in other embodiments, the material compositions of the electrodes 312 and 316 may be different.

In some embodiments, the electrode 312 or the electrode 316 may include a material having a work function that is less than 4.5 electron volts (referred to herein as a “low work function material”). Examples of such materials may include carbon, tantalum, titanium, and hafnium. In some embodiments, an electrode 312/316 including a low work function material (referred to herein as a “low work function electrode”) may be the injecting electrode. Using a low work function material in the injecting electrode 312/316 may reduce the Schottky barrier height of the electrode 312/316, reducing the contact resistance of the electrode 312/316 and reducing the value of the threshold voltage Von. The threshold voltage Von may thus be adjusted by, among other factors, appropriately selecting the low work function material included in the injecting electrode 312/316. When a low work function electrode 312/316 acts as the injecting electrode, an adjacent getter layer 315 may be included in the selector device 330; the getter layer 315 may mitigate gettering of the low work function electrode 312/316.

In some embodiments, one of the electrodes 312/316 may be a low work function electrode, and the other of the electrodes 312/316 may include a material having a work function that is greater than 4.5 electron volts (referred to herein as a “high work function material”). Examples of high work function materials may include gold, platinum, ruthenium, and copper, among others. An electrode 312/316 including a high work function material may be referred to herein as a “high work function electrode”). In some particular embodiments, the low work function electrode 312/316 may be the injecting electrode, and the high work function electrode 312/316 may be the non-injecting electrode. When a low work function electrode 312/316 is the injecting electrode, using a high work function electrode 312/316 as the non-injecting electrode may reduce the holding voltage Vhold (and maintain the threshold voltage Von) relative to an embodiment in which a low work function electrode 312/316 is the non-injecting electrode. Thus, by selecting the materials of the injecting and non-injecting electrodes 312/316, the threshold voltage Von and the holding voltage Vhold may be tuned to desired levels.

In some particular embodiments, the low work function electrode 312/316 may be the non-injecting electrode, and the high work function electrode 312/316 may be the injecting electrode. When a low work function electrode 312/316 is the non-injecting electrode, using a high work function electrode 312/316 as the injecting electrode may reduce the threshold voltage Von (and maintain the holding voltage Vhold) relative to an embodiment in which a low work function electrode 312/316 is the injecting electrode. Thus, as noted above, by selecting the materials of the injecting and non-injecting electrodes 312/316, the threshold voltage Von and the holding voltage Vhold may be tuned to desired levels.

In some embodiments, a selector device 330 may include a getter layer 315 on the non-injecting electrode 312/316. In particular, a selector device 330 may include the getter layer 315-1 if the non-injecting electrode is the electrode 312, or the selector device 330 may include the getter layer 315-2 if the non-injecting electrode is the electrode 316. The use of a getter layer 315 on a non-injecting electrode 312/316 may cause vacancy doping in the selector material 314, and thus may reduce the effective thickness of the selector material 314. Consequently, the contact resistance at the non-injecting electrode 312/316 may decrease relative to an embodiment in which the getter layer 315 is not present, lowering the threshold voltage Von and the holding voltage Vhold.

In some embodiments, the selector material 314 may include niobium, tantalum, vanadium, titanium, or hafnium. For example, the selector material 314 may be an oxide material (e.g., niobium oxide, tantalum oxide, vanadium oxide, titanium oxide, or hafnium oxide) that may be capable of undergoing an insulator-to-metal transition in response to an applied voltage or resistance. For example, the selector material 314 may be TaO0.5-1.7 (e.g., TaO1.5). In some embodiments, the selector material 314 may be a non-oxide material. For example, the dielectric material may be a chalcogenide material, a multi-component material including group IV or group VI elements, such as silicon and tellurium. Examples of chalcogenides that may serve as the selector material 314 may include germanium silicon selenium, germanium silicon tellurium, and silicon tellurium arsenic germanium, among others.

In some embodiments of the selector devices 330 disclosed herein, the geometries of the electrodes 312 and 316 may be the same, or may differ. For example, the electrodes 312 and 316 may have the same or different surface areas. In some embodiments, the cross-sectional width 343 of the electrode 312, the selector material 314, the getter layer(s) 315, and/or the electrode 316 may be between about 5 nanometers and 50 nanometers.

The thicknesses of the materials included in the selector device 330 of FIG. 7 may take any suitable values. For example, in some embodiments, the electrode 312 may have a thickness 332 between about 1 nanometer and 100 nanometers, the selector material 314 may have a thickness 334 between about 2 nanometers and 80 nanometers, the getter layer(s) 315 may have a thickness 335 between about 0.5 nanometers and 50 nanometers, and the electrode 316 may have a thickness 336 between about 1 nanometer and 100 nanometers.

For example, one particular embodiment of a selector device 330 may include a tantalum electrode 312 having a thickness 332 of about 30 nanometers, a tantalum oxide selector material 314 having a thickness 334 of about 28 nanometers, a tantalum getter layer 315-2 having a thickness 335 of about 20 nanometers, and a platinum electrode 316 having a thickness 336 of about 10 nanometers.

In another example, one particular embodiment of a selector device 330 may include a tantalum electrode 316 having a thickness 336 of about 30 nanometers, a tantalum oxide selector material 314 having a thickness 334 of about 28 nanometers, a tantalum getter layer 315-1 having a thickness 335 of about 20 nanometers, and a platinum electrode 312 having a thickness 332 of about 10 nanometers.

In another example, one particular embodiment of a selector device 330 may include a low work function electrode 312 (including, for example, carbon, tantalum, titanium, or hafnium) and a titanium nitride getter layer 315-1 having a thickness 335 between about 0.5 nanometers and 2 nanometers (e.g., between about 0.5 nanometers and 1 nanometer).

In another example, one particular embodiment of a selector device 330 may include a low work function electrode 316 (including, for example, carbon, tantalum, titanium, or hafnium) and a titanium nitride getter layer 315-2 having a thickness 335 between about 0.5 nanometers and 2 nanometers (e.g., between about 0.5 nanometers and 1 nanometer).

FIG. 7A illustrates an embodiment of the selector devices 330 in which the electrodes 312/316 each have a substantially uniform composition. FIG. 7B illustrates an embodiment of the selector devices 330 in which the electrode 312 is formed of a bulk conductive material 312-1 having a skin layer 312-2 on opposite faces of the bulk conductive material 312-1, and in which the electrode 316 is formed of a bulk conductive material 316-1 having a skin layer 316-2 on opposite faces of the bulk conductive material 316-1. In some embodiments of the selector devices 330 disclosed herein, one of the electrodes 312/316 may have a uniform material composition (as illustrated in FIG. 7A) while the other of the electrodes 312/316 may include a skin layer.

The bulk conductive materials 312-1/316-1 may include any suitable conductive materials, such as metals or other conductive materials (e.g., tantalum, titanium, tungsten, copper, carbon, metal nitrides such as titanium nitride or tantalum nitride, etc.). The skin layers 312-2/316-2 may take the form of any of the materials discussed above with reference to the electrodes 312 and 316. For example, in some embodiments, a low work function electrode 312/316 may have a skin layer 312-2/316-2 including a low work function material, while the bulk conductive material 312-1/316-1 may or may not include a low work function material. Similarly, in some embodiments, a high work function electrode 312/316 may have a skin layer 312-2/316-2 including a high work function material, while the bulk conductive material 312-1/316-1 may or may not include a high work function material.

In some embodiments, a thickness 337 of a skin layer 312-2/316-2 may be greater than about 1 nanometer (e.g., between about 1 nanometer and 10 nanometers, or between about 1 nanometer and 20 nanometers). The other dimensions of the selector device 330 of FIG. 7B may take any of the forms discussed above.

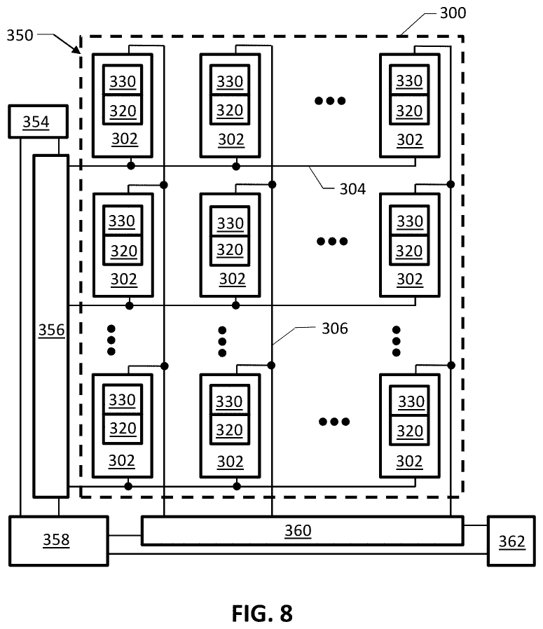

A memory array 300 including a selector device 330 may be controlled in any suitable manner. For example, FIG. 8 is a schematic illustration of a cross-point memory device 350 including a memory array 300 having memory cells 302 with storage elements 320 and selector devices 330, in accordance with various embodiments. As discussed above, each memory cell 302 may include a storage element 320 connected in series with any of the embodiments of the selector devices 330 disclosed herein. The memory device 350 of FIG. 8 may be a bidirectional cross-point array in which each column is associated with a BL 306 driven by column select circuitry 360. Each row may be associated with a WL 304 driven by row select circuitry 356. During operation, read/write control circuitry 358 may receive memory access requests (e.g., from one or more processing devices or communication chips of a computing device, such as the computing device 2400 discussed below), and may respond by generating an appropriate control signal (e.g., read, write 0, or write 1), as known in the art. The read/write control circuitry 358 may control the row select circuitry 356 and the column select circuitry 360 to select the desired memory cell(s) 302. Voltage supplies 354 and 362 may be controlled to provide the voltage(s) necessary to bias the memory array 300 to facilitate the requested action on one or more memory cells 302. Row select circuitry 356 and column select circuitry 360 may apply appropriate voltages across the memory array 300 to access the selected memory cells 302 (e.g., by providing appropriate voltages to the memory cells 302 to allow the desired selector devices 330 to conduct). Row select circuitry 356, column select circuitry 360, and read/write control circuitry 358 may be implemented using any devices and techniques known in the art. In some embodiments, the memory array 300 may be implemented in the BEOL layer 190 of the IC device 100, while various control circuitry for the memory array 300 may be implemented in the FEOL layer 120.

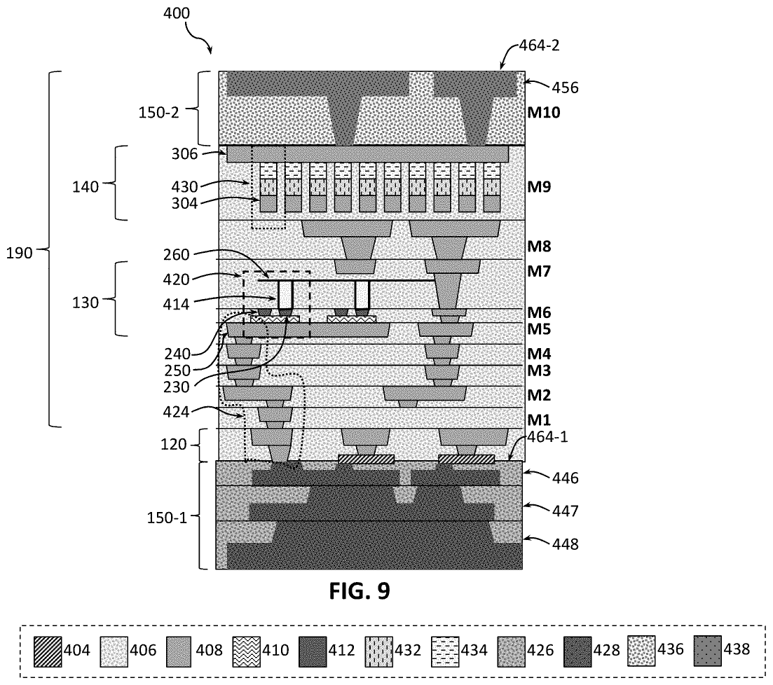

FIG. 9 provides a cross-sectional view of an example IC device 400 with stacked two-level backend memory, according to various embodiments of the present disclosure. A number of elements labeled in FIG. 9 with reference numerals are illustrated in the drawing with different patterns, with a legend showing the correspondence between the reference numerals and patterns being provided at the bottom of the page of the drawing. For example, the legend illustrates that FIG. 9 uses different patterns to show frontend transistors 404, an ILD material 406, backend interconnects 408, etc. Furthermore, although a certain number of a given element may be illustrated in FIG. 9, this is also simply for ease of illustration, and more, or less, than that number may be included in an IC device according to various embodiments of the present disclosure. Still further, FIG. 9 is intended to show relative arrangements of various elements in example IC devices with stacked two-level backend memory, and that various IC devices with stacked two-level backend memory, or portions thereof, may include other elements or components that are not illustrated (e.g., any further materials, such as spacer materials that may surround the gate stack of the transistors, etch-stop materials, etc.).

The IC device 400 may be an example implementation of the IC device 100, which is indicated in FIG. 9 by labeling the FEOL layer 120, the first memory layer 130, the second memory layer 140, and the power and signal interconnect layer 150 on the left side of FIG. 9.

As shown in FIG. 9, in some embodiments, the FEOL layer 120 may include frontend devices 404, e.g., frontend transistors 404. The details of the frontend transistors 404 are not shown in FIG. 9 because various architectures of such transistors are known and the frontend transistors 404 may include transistors of any architecture as known in the art.

FIG. 9 further illustrates an ILD material 406 and a plurality of backend interconnects 408 above the frontend transistors 404. In various embodiments, the ILD material 406 may include any suitable ILD materials such as silicon oxide, carbon-doped silicon oxide, silicon carbide, silicon nitride, aluminum oxide, and/or silicon oxynitride. In various embodiments, the ILD material 406 may include any of the low-k dielectric materials described above. In various embodiments, the backend interconnects 408 may include any of the electrically conductive materials described above.

A portion of the ILD material 406 directly above and surrounding portions of the frontend transistors 404, and one or more of the backend interconnects 408 in that portion of the ILD material 406 may be seen as a part of the FEOL layer 120, whereas everything above may be seen as a part of the BEOL layer 190, as labeled in FIG. 9. In particular, the BEOL layer 190 may include a metallization stack of a plurality of metal layers labeled in FIG. 9 as a metal layer 1 (M1), a metal layer 2 (M2), and so on. Although not specifically shown in FIG. 9, a layer of an etch-stop (ES) material may be present between at least portions of adjacent metal layers of the BEOL layer 190, as known in the art.

In some embodiments, a single layer of backend memory cells may occupy a plurality of consecutive metal layers of the metallization stack of an IC device. This is shown in FIG. 9 with the 1T-1C backend memory being in the metal layers M5, M6, and M7. In particular, FIG. 9 illustrates access transistors 410, S/D contacts 412 for the access transistors 410, and capacitors 414. FIG. 9 further provides a label for a memory cell 420, illustrated in FIG. 9 within a dashed rectangular contour, that includes one access transistor 410 and one capacitor 414, coupled to one of the S/D contacts 412 of the access transistor 410. Thus, the memory cell 420 is an example of a 1T-1C memory cell, e.g., the memory cell 200 as described above, where the access transistor 410 is an example of the access transistor 110, and the capacitor 414 is an example of the capacitor 220, described above. In particular, the access transistor 410 is a backend transistor and the memory cell 420 is a backend memory cell. Two such memory cells 420 are shown in FIG. 9, but only one is labeled with reference numerals in order to not clutter the drawing. A plurality of memory cells 420 may be included in the first memory layer 130. The memory cell 420 may be a backend memory cell according to any of the embodiments described above, e.g., an eDRAM memory cell as explained with reference to FIGS. 2-5. For example, as shown in FIG. 9, in some embodiments of the memory cell 420, one of the backend interconnects 408 in a metal layer M5 may form a WL such as the WL 250, described above, while the access transistor 410, a storage node such as the storage node 230, and a BL such as the BL 240 may be formed in a metal layer M6 of the BEOL layer 190 (i.e., the metal layer directly above the metal layer M5), and the capacitor 414 may then be formed in a metal layer M7 (i.e., the metal layer directly above the metal layer M6). FIG. 9 further illustrates a PL such as the PL 260, described above, which may be coupled to one of the backend interconnects 408 in the metal layer M7. In other embodiments of the IC device 400, backend memory with memory cells as the memory cell 420 may be implemented in other metal layers of the BEOL layer 190, any number of memory cells 420 may be included in the first memory layer 130, and multiple layers of backend memory cells such as the memory cell 420 may be stacked over one another, thus implementing three-dimensional (3D) stacked backend memory.

Turning to the second memory layer 140, as shown in FIG. 9, the second memory layer 140 may include a plurality of memory cells 430 (one of which is labeled, as illustrated within a dotted rectangular contour), each of which may include a storage element 432 and an associated selector device 434. The memory cell 430 is an example of a memory cell of a cross-point memory array, e.g., the memory cell 302 as described above, where the storage element 432 is an example of the storage element 320, and the selector device 434 is an example of the selector device 330, described above. FIG. 9 also illustrates how a plurality of the memory cells 430 may be coupled to a single BL 306 and how different ones of the memory cells 430 may be coupled to respective/associated (i.e., different) WLs 304, where each of the BL 306 and the WLs 304 may be implemented as respective backend interconnects 408. FIG. 9 illustrates that the plurality of the memory cells 430 may be implemented in the metal layer M9 of the BEOL layer 190, thus realizing the second memory layer 140. In other embodiments of the IC device 400, backend memory with memory cells as the memory cell 430 may be implemented in other metal layers of the BEOL layer 190, any number of memory cells 430 may be included in the second memory layer 140, and multiple layers of backend memory cells such as the memory cell 430 may be stacked over one another, thus implementing 3D stacked backend memory. Still in further embodiments, the memory cells 420 as described herein may be included in the second memory layer 140, while the memory cells 430 as described herein may be included in the first memory layer 130.

As described above, in some embodiments, the power and signal interconnect layer 150 may be implemented at the back side of the IC device 100, so that the FEOL layer 120 is between the power and signal interconnect layer 150 and the BEOL layer 190, or some portions of the power and signal interconnect layer 150 may be implemented at the back side of the IC device 100 while other portions of the power and signal interconnect layer 150 may be implemented at the front side of the IC device 100. Such an embodiment is illustrated in FIG. 9, showing that the IC device 400 may include a first power and signal interconnect layer 150-1 at the back of the FEOL layer 120, and further include a second power and signal interconnect layer 150-2 at the front of the FEOL layer 120. As shown in FIG. 9, the first power and signal interconnect layer 150-1 may be arranged so that the FEOL layer 120 is between the first power and signal interconnect layer 150-1 and the first memory array 130, while the second power and signal interconnect layer 150-2 may be arranged so that the second memory array 140 is between the first memory array 130 and the second power and signal interconnect layer 150-2. In such embodiments, the channel regions of the frontend transistors 404 may include a semiconductor material that may originally be a portion of the support structure 110 of the IC device 400, which is later removed and replaced by the first power and signal interconnect layer 150-1.

In general, each of the first and second power and signal interconnect layers 150-1 and 150-2 may be configured for providing power and/or signal and/or control commands to any of the memory cells 420, 430, and/or to the frontend transistors 404 of the IC device 400. For example, in some embodiments, the first power and signal interconnect layer 150-1 may be configured to deliver power, while the second power and signal interconnect layer 150-2 may be configured to deliver signals to any of the memory cells 420, 430, and/or to the frontend transistors 404 of the IC device 400.

Together, the FEOL layer 120 and the BEOL layer 190 of the IC device 400 may be seen as a part of an IC structure 401 in which a support structure on which the frontend transistors 404 were built has been removed and replaced by the first power and signal interconnect layer 150-1. To that end, a back side 464-1 and a front side 464-2 of the IC structure 401 may be defined as shown in FIG. 9, illustrating that the back side 464-1 is the side where the support structure was removed and the first power and signal interconnect layer 150-1 was provided, and illustrating that the front side 464-2 is the face of the IC structure 401 that is opposite the back side 464-2, e.g., the surface of the BEOL layer 190.

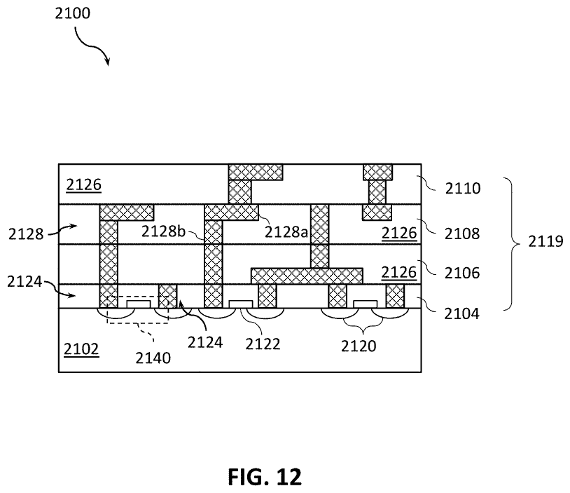

As shown in FIG. 9, the first power and signal interconnect layer 150-1 may include a back-side insulator 426 and a plurality of back-side interconnects 428 that may be coupled to any of the memory cells 420, 430 of the backend memory implemented in the BEOL layer 190 in order to provide power and/or signal to the backend memory. In some embodiments, the back-side interconnects 428 may also be coupled to the frontend transistors 404, to provide power and/or signals to those components as well. The back-side interconnects 428 may include any suitable back-side interconnect structures, such as trench structures (i.e., conductive lines) and/or via structures (i.e., conductive vias), e.g., as described below with reference to the interconnect structures 2128, shown in FIG. 12. In some embodiments, the back-side interconnects 428 may be arranged within back-side interconnect layers 446-448 to route electrical signals to/from the backend memory in the BEOL layer 190 according to a wide variety of designs (in particular, the arrangement is not limited to the particular configuration of the back-side interconnects 428 depicted in FIG. 9). Although a particular number of interconnect layers 446-448 in which the back-side interconnects 428 are disposed is depicted in FIG. 9, embodiments of the present disclosure include IC devices having more or fewer interconnect layers 446-448 with the back-side interconnects 428 than depicted. The interconnect layers 446-448 may be similar to the interconnect layers 2106-2110 shown in FIG. 102 but at the back side of the IC structure 401. In some embodiments, the back-side interconnects 428 may be coupled to a given memory cell 420 and/or 430 by an electrical feedthrough network of the backend interconnects 408. An example of this is shown in FIG. 9 with an electrical feedthrough network 424 (shown in FIG. 9 within a dotted contour labeled in FIG. 9 with the reference numeral “424”) of the backend interconnects 408, coupling one of the back-side interconnect 428 to the memory cell 420. Analogously, one or more of the back-side interconnect 428 may be coupled to any of the memory cells 430.

As also shown in FIG. 9, the second power and signal interconnect layer 150-2 may include a front-side insulator 436 and a plurality of front-side interconnects 438 that may be coupled to any of the memory cells 420, 430 of the backend memory implemented in the BEOL layer 190 in order to provide power and/or signal to the backend memory. In some embodiments, the front-side interconnects 438 may also be coupled to the frontend transistors 304, to provide power and/or signals to those components as well. The front-side interconnects 438 may include any suitable front-side interconnect structures, such as conductive trench structures (i.e., conductive lines) and/or via structures (i.e., conductive vias), e.g., as described below with reference to the interconnect structures 2128, shown in FIG. 12. In some embodiments, the front-side interconnects 438 may be arranged within one or more front-side interconnect layers 456 to route electrical signals to/from the backend memory in the BEOL layer 190 according to a wide variety of designs (in particular, the arrangement is not limited to the particular configuration of the front-side interconnects 438 depicted in FIG. 9 or other drawings). Although a particular number of interconnect layers 456 in which the front-side interconnects 438 are disposed is depicted in FIG. 9, embodiments of the present disclosure include IC devices having more interconnect layers 456 with the front-side interconnects 438 than depicted. The interconnect layers 456 may be similar to the interconnect layers 2106-2110 shown in FIG. 12, at the front side of the IC structure 401. In some embodiments, the front-side interconnects 438 may be coupled to one or more memory cells 420, 430 by an electrical feedthrough network of the backend interconnects 408 (not specifically shown in FIG. 9), similar to how the back-side interconnect 428 may be coupled to one or more memory cells 420, 430 with the electrical feedthrough network 424.

In various embodiments, the backend interconnects 408, the back-side interconnects 428, and the front-side interconnects 438 may be implemented as known in the art. For example, in some embodiments, any of the backend interconnects 408, the back-side interconnects 428, and the front-side interconnects 438 may include an electrically conductive fill material and, optionally, a liner. The electrically conductive fill material may include one or more of copper, tungsten, aluminum, ruthenium, cobalt, etc. (e.g., in proportions of between 1:1 to 1:100), or any of the electrically conductive materials described above. The liner may be an adhesion liner and/or a barrier liner. For example, the liner may be a liner having one or more of tantalum, tantalum nitride, titanium nitride, tungsten carbide, cobalt, etc. In the liner and/or in the electrically conductive fill material of any of the backend interconnects 408, the back-side interconnects 428, and the front-side interconnects 438, any of the individual materials (e.g., any of the examples listed above) may be included in the amount of between about 1% and 75%, e.g., between about 4% and 40%, indicating that these materials are included by intentional alloying of materials, in contrast to potential accidental doping or impurities being included, which would be less than about 0.1% for any of these metals. In general, material compositions of liners and/or electrically conductive fill materials of any of the backend interconnects 408, the back-side interconnects 428, and the front-side interconnects 438 may, but do not have to be, the same. The back-side insulator 426 and the front-side insulator 436 may include any of the materials described with reference to the ILD 406, where, in general, material compositions of any of the back-side insulator 426, the front-side insulator 436, and the ILD 406 may, but do not have to be, the same.

Although the IC device 400 is illustrated in FIG. 9 for the example of DRAM being the first type of the first memory layer 130 and cross-point memory being the second type of the second memory layer 140, in other embodiments, the IC device 400 with stacked two-level backend memory may include memory cells of other types.

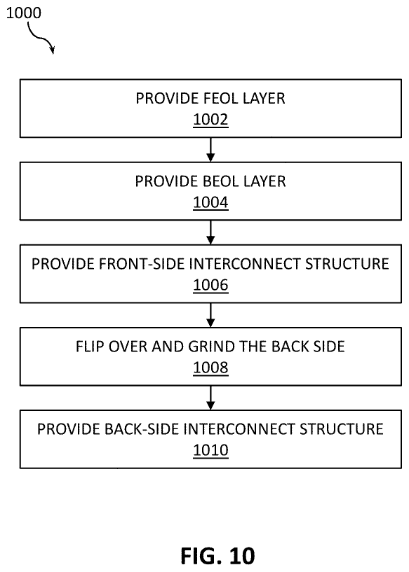

Any suitable techniques may be used to manufacture the IC device 100 with stacked two-level backend memory disclosed herein, e.g., subtractive, additive, damascene, dual damascene, etc. Some of such techniques may include suitable deposition and patterning techniques. As used herein, “patterning” may refer to forming a pattern in one or more materials using any suitable techniques (e.g., applying a resist, patterning the resist using lithography, and then etching the one or more material using dry etching, wet etching, or any appropriate technique). FIG. 10 is a flow diagram of an illustrative method 1000 of manufacturing an IC device with stacked two-level backend memory, according to some embodiments of the present disclosure. Although the operations discussed below with reference to the method 1000 are illustrated in a particular order and depicted once each, these operations may be repeated or performed in a different order (e.g., in parallel), as suitable. Additionally, various operations may be omitted, as suitable. Various operations of the method 1000 may be illustrated with reference to one or more of the embodiments discussed above, but the method 1000 may be used to manufacture any suitable IC device with stacked two-level backend memory (including any suitable ones of the embodiments disclosed herein). The example fabrication method shown in FIG. 10 may include other operations not specifically shown in FIG. 10, such as various cleaning or planarization operations as known in the art. For example, in some embodiments, any of the layers of the IC device may be cleaned prior to, after, or during any of the processes of the fabrication method described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the top surfaces of the IC devices described herein may be planarized prior to, after, or during any of the processes of the fabrication method described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

As shown in FIG. 10, the method 1000 may include a process 1002 that includes providing a FEOL layer over a semiconductor support structure (e.g., the FEOL layer 120 as described herein). The method 1000 may also include a process 1004 that includes providing a BEOL layer (e.g., the BEOL layer 190 as described herein) over the FEOL layer provided in the process 1002. In particular, the process 1004 includes providing at least two different types of memory in the BEOL layer 190, e.g., the first and second memory layers 130, 140, as described herein. In some embodiments, if any of the backend memory cells implemented in the BEOL layer 190 include semiconductor material, e.g., in channel regions of the access transistors of 1T-1C memory cells as described herein, such semiconductor material may be included in the BEOL layer 190 using either monolithic integration approach (i.e., by directly depositing the semiconductor material in the BEOL layer 190), e.g., to form TFTs, or using layer transfer approach, as described above. Whether a semiconductor material in the BEOL layer 190 has been provided by monolithic integration approach or by layer transfer can be identified by inspecting grain size of active semiconductor material of the IC device, as described above. The method 1000 may further include a process 1006 that includes providing a front-side interconnect structure (e.g., the second power and signal interconnect layer 150-2 as described herein) over the BEOL layer provided in the process 1004. The method 1000 may also include a process 1008 that includes flipping the IC device resulting from the previous process of the method 1000 over and grinding (or polishing) the back side of the IC device (e.g., to expose/reveal the back of the FEOL layer provided in the process 1002) performing further processing on the other side. For example, if the process 1008 is performed after the process 1006, as shown in FIG. 10, then next the method 1000 may include a process 1010 that includes providing a back-side interconnect structure (e.g., the first power and signal interconnect layer 150-1 as described herein) over the exposed back of the FEOL layer, provided in the process 1008. In other embodiments, the processes of the method 1000 may be performed in different order. For example, any of the process 1004 and the process 1006 may be performed after the process 1010.

Because of different fabrication processes being performed on different sides during the fabrication of the IC devices 100/400 in some embodiments, these devices may exhibit characteristic features indicative of the fabrication method as shown in FIG. 10. In particular, for certain manufacturing processes, cross-sectional shapes of various interconnects in the plane such as that shown in FIG. 9 may be trapezoidal, i.e., a cross-section of an interconnect may have two parallel sides, one of which is a short side and another one of which is a long side. For example, dual damascene or single-damascene processes for manufacturing interconnects could result in such trapezoidal cross-sections. Therefore, examining the trapezoidal cross-sectional shapes of the backend interconnects 408, the back-side interconnects 428, and the front-side interconnects 438 may reveal characteristic features of the fabrication method as shown in FIG. 10. In particular, the short sides of the trapezoidal cross-sections of the backend interconnects 408 and of the front-side interconnects 438 may be closer to the first power and signal interconnect layer 150-1 (or to the support structure 110) than their long sides, or, phrased differently, the long sides of the trapezoidal cross-sections of the backend interconnects 408 and of the front-side interconnects 438 may be closer to the front side 464-2 than their short sides. Furthermore, the short sides of the trapezoidal cross-sections of the back-side interconnects 428 may be closer to the FEOL layer 120 than their long sides, or, phrased differently, the long sides of the trapezoidal cross-sections of the back-side interconnects 428 may be further away from to the front side 464-2 than their short sides.

### Example Electronic Devices

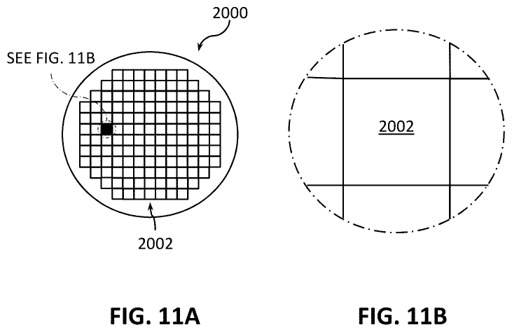

IC devices with stacked two-level backend memory as disclosed herein may be included in any suitable electronic device. FIGS. 11-15 illustrate various examples of devices and components that may include one or more IC devices with stacked two-level backend memory as disclosed herein.

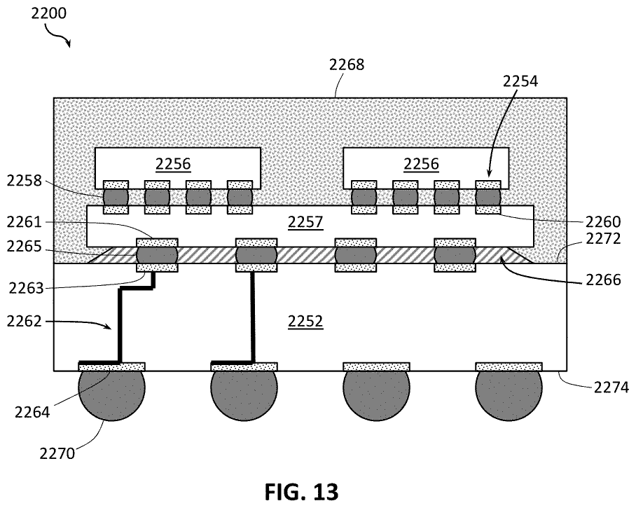

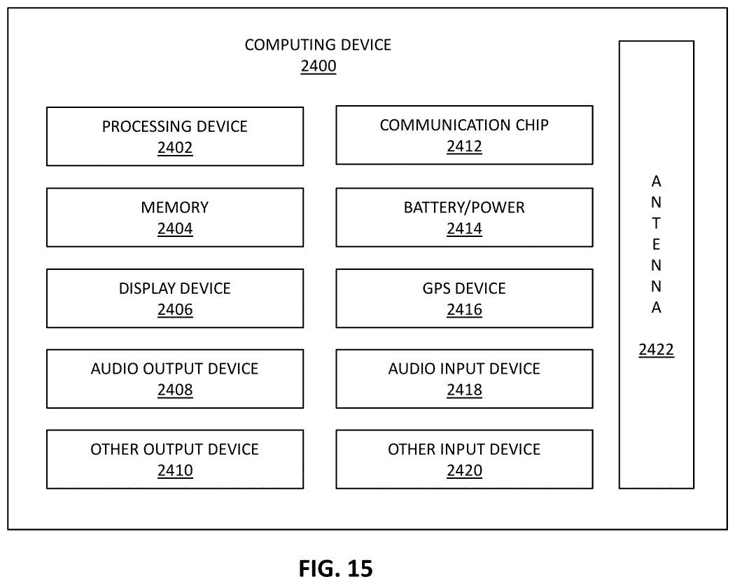

FIGS. 11A-11B are top views of a wafer 2000 and dies 2002 that may include one or more IC devices with stacked two-level backend memory in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 13. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., ICs including stacked two-level backend memory as described herein). After the fabrication of the semiconductor product is complete (e.g., after manufacture of stacked two-level backend memory as described herein, e.g., any embodiment of the IC devices with stacked two-level backend memory, described herein), the wafer 2000 may undergo a singulation process in which each of the dies 2002 is separated from one another to provide discrete “chips” of the semiconductor product. In particular, devices that include stacked two-level backend memory as disclosed herein may take the form of the wafer 2000 (e.g., not singulated) or the form of the die 2002 (e.g., singulated). The die 2002 may include one or more transistors (e.g., one or more transistors of the FEOL layer 120 and one or more transistors of the BEOL layer 190, as described herein and/or one or more FEOL transistors 2140 of FIG. 12, discussed below), one or more memory layers (e.g., the memory layers 130, 140 as described herein), and/or supporting circuitry (e.g., one or more interconnects as described herein) to route electrical signals to the transistors and/or the memory cells, as well as any other IC components. In some embodiments, the wafer 2000 or the die 2002 may implement or include a memory device, a logic device (e.g., an AND, OR, NAND, or NOR gate), or any other suitable circuit element. Multiple ones of these devices may be combined on a single die 2002. For example, a memory array formed by multiple memory cells in a given layer may be formed on a same die 2002 as a processing device (e.g., the processing device 2402 of FIG. 15) or other logic that is configured to store information in the memory devices or execute instructions stored in the memory array.

FIG. 12 is a cross-sectional side view of one side of an IC device 2100 that may include stacked two-level backend memory in accordance with any of the embodiments disclosed herein. For example, the IC device 2100 may be, or may include, the IC device 100, described above, i.e., may be an IC device with stacked two-level backend memory, as described herein. In particular, the different memory layers 130, 140 as described herein may be implemented in any of the BEOL layers of the IC device 2100, e.g., in any of the interconnect layers 2106-2110 shown in FIG. 12. Because there are various possibilities where such stacked two-level backend memory may be integrated in the IC device 2100, the memory layers 130, 140 are not specifically shown in FIG. 12. For example, in some embodiments, any of the memory layers 130, 140 as described herein may be included above the interconnect layers 2106-2110 of the IC device 2100. In another example, at least some of the memory layers 130, 140 as described herein may be included within one or more of the interconnect layers 2106-2110 of the IC device 2100. In some embodiments, the IC device 2100 may serve as any of the dies 2256 in the IC package 2300.

As shown in FIG. 12, the IC device 2100 may be formed on a substrate 2102 (e.g., the wafer 2000 of FIG. 11A) and may be included in a die (e.g., the die 2002 of FIG. 11B). The substrate 2102 may include any material that may serve as a foundation for an IC device 2100. The substrate 2102 may be a semiconductor substrate and may include any of the examples described above with reference to the support structure 110. Although a few examples of the substrate 2102 are described here, any material or structure that may serve as a foundation upon which an IC device 2100 may be built falls within the spirit and scope of the present disclosure. The substrate 2102 may be part of a singulated die (e.g., the die 2002 of FIG. 11B) or a wafer (e.g., the wafer 2000 of FIG. 11A).

The IC device 2100 may include one or more device layers 2104 disposed on the substrate 2102. The device layers 2104 provide one example of one or more layers with the logic devices (e.g., frontend transistors) of the FEOL layer 120, described above. The device layer 2104 may include features of one or more transistors 2140 (e.g., metal oxide semiconductor field-effect transistors (MOSFETs)) formed on the substrate 2102. The transistors 2140 provide one example of any of the transistors of the FEOL layer 120, described above. The device layer 2104 may include, for example, one or more S/D regions 2120, a gate 2122 to control current flow in the transistors 2140 between the S/D regions 2120, and one or more S/D contacts 2124 to route electrical signals to/from the S/D regions 2120. The transistors 2140 may include additional features not depicted for the sake of clarity, such as device isolation regions, gate contacts, and the like.

Each transistor 2140 may include a gate 2122 formed of at least two layers, a gate dielectric layer and a gate electrode layer. Generally, the gate dielectric layer of a transistor 2140 may include one layer or a stack of layers, and may include any of the materials described above with reference to the gate dielectric 216.

The gate electrode may be formed on the gate dielectric and may include at least one P-type work function metal or N-type work function metal, depending on whether the transistor 2140 is to be a PMOS or an NMOS transistor. In some implementations, the gate electrode may include a stack of two or more metal layers, where one or more metal layers are work function metal layers and at least one metal layer is a fill metal layer. Further metal layers may be included for other purposes, such as a barrier layer. The gate electrode of the gate 2122 may include any of the materials described above with reference to the gate electrode 214.

In some embodiments, when viewed as a cross-section of the transistor 2140 along the source-channel-drain direction, the gate electrode of the gate 2122 may include a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may include a combination of U-shaped structures and planar, non-U-shaped structures. For example, the gate electrode may include one or more U-shaped metal layers formed atop one or more planar, non-U-shaped layers. In some embodiments, the gate electrode may include a V-shaped structure (e.g., when the fin of a FinFET does not have a “flat” upper surface, but instead has a rounded peak).

In some embodiments, a pair of sidewall spacers may be formed on opposing sides of the gate stack to bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 2120 may be formed within the substrate 2102, e.g., adjacent to the gate of each transistor 2140. The S/D regions 2120 may be formed using an implantation/diffusion process or an etching/deposition process, for example. In the former process, dopants such as boron, aluminum, antimony, phosphorous, or arsenic may be ion-implanted into the substrate 2102 to form the S/D regions 2120. An annealing process that activates the dopants and causes them to diffuse farther into the substrate 2102 may follow the ion-implantation process. In the latter process, the substrate 2102 may first be etched to form recesses at the locations of the S/D regions 2120. An epitaxial deposition process may then be carried out to fill the recesses with material that is used to fabricate the S/D regions 2120. In some implementations, the S/D regions 2120 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 2120 may be formed using one or more alternate semiconductor materials such as germanium or a group III-V material or alloy. In further embodiments, one or more layers of metal and/or metal alloys may be used to form the S/D regions 2120.

Various transistors 2140 are not limited to the type and configuration depicted in FIG. 12 and may include a wide variety of other types and configurations such as, for example, planar transistors, non-planar transistors (e.g., FinFETs, nanowire, or nanoribbon transistors), or a combination of both.

Electrical signals, such as power and/or input/output (I/O) signals, may be routed to and/or from the transistors 2140 of the device layer 2104 through one or more interconnect layers disposed on the device layer 2104 (illustrated in FIG. 12 as interconnect layers 2106-2110). For example, electrically conductive features of the device layer 2104 (e.g., the gate 2122 and the S/D contacts 2124) may be electrically coupled with the interconnect structures 2128 of the interconnect layers 2106-2110. The one or more interconnect layers 2106-2110 may form an ILD stack 2119 of the IC device 2100.

The interconnect structures 2128 may be arranged within the interconnect layers 2106-1210 to route electrical signals according to a wide variety of designs (in particular, the arrangement is not limited to the particular configuration of interconnect structures 2128 depicted in FIG. 12). Although a particular number of interconnect layers 2106-1210 is depicted in FIG. 12, embodiments of the present disclosure include IC devices having more or fewer interconnect layers than depicted.

In some embodiments, the interconnect structures 2128 may include trench structures 2128a (sometimes referred to as “lines”) and/or via structures 2127 (sometimes referred to as “holes”) filled with an electrically conductive material such as a metal. The trench structures 2128a may be arranged to route electrical signals in a direction of a plane that is substantially parallel with a surface of the substrate 2102 upon which the device layer 2104 is formed. For example, the trench structures 2128a may route electrical signals in a direction in and out of the page from the perspective of FIG. 12. The via structures 2127B may be arranged to route electrical signals in a direction of a plane that is substantially perpendicular to the surface of the substrate 2102 upon which the device layer 2104 is formed. In some embodiments, the via structures 2127B may electrically couple trench structures 2128a of different interconnect layers 2106-2110 together.

The interconnect layers 2106-2110 may include a dielectric material 2126 disposed between the interconnect structures 2128, as shown in FIG. 12. In some embodiments, the dielectric material 2126 disposed between the interconnect structures 2128 in different ones of the interconnect layers 2106-2110 may have different compositions; in other embodiments, the composition of the dielectric material 2126 between different interconnect layers 2106-2110 may be the same. The dielectric material 2126 may include any of the insulator/dielectric materials described above.

A first interconnect layer 2106 (referred to as Metal 1 or “M1”) may be formed directly on the device layer 2104. In some embodiments, the first interconnect layer 2106 may include trench structures 2128a and/or via structures 21273, as shown. The trench structures 2128a of the first interconnect layer 2106 may be coupled with contacts (e.g., the S/D contacts 2124) of the device layer 2104.

A second interconnect layer 2108 (referred to as Metal 2 or “M2”) may be formed directly on the first interconnect layer 2106. In some embodiments, the second interconnect layer 2108 may include via structures 21273 to couple the trench structures 2128a of the second interconnect layer 2108 with the trench structures 2128a of the first interconnect layer 2106. Although the trench structures 2128a and the via structures 21273 are structurally delineated with a line within each interconnect layer (e.g., within the second interconnect layer 2108) for the sake of clarity, the trench structures 2128a and the via structures 21273 may be structurally and/or materially contiguous (e.g., simultaneously filled during a dual damascene process) in some embodiments.

A third interconnect layer 2110 (referred to as Metal 3 or “M3”) (and additional interconnect layers, as desired) may be formed in succession on the second interconnect layer 2108 according to similar techniques and configurations described in connection with the second interconnect layer 2108 or the first interconnect layer 2106.

The interconnect layers 2106-2110 may be the metal layers M1-M3, described above. Further metal layers may be present in the IC device 2100, as also described above.

FIG. 13 is a side, cross-sectional view of an example IC package 2200 that may include one or more IC devices with stacked two-level backend memory in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274. These conductive pathways may take the form of any of the interconnect structures 2128 discussed above with reference to FIG. 12.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 13 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 13 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

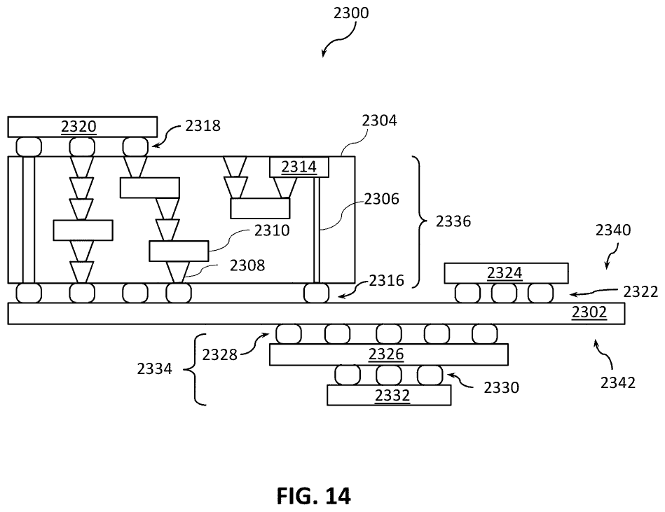

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 13 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 14.

The dies 2256 may take the form of any of the embodiments of the die 2002 discussed herein (e.g., may include any of the embodiments of the IC device 2100). In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high bandwidth memory), including embedded memory dies as described herein. In some embodiments, any of the dies 2256 may include stacked two-level backend memory, e.g., as discussed above; in some embodiments, at least some of the dies 2256 may not include stacked two-level backend memory.

The IC package 2200 illustrated in FIG. 13 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 13, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 14 is a cross-sectional side view of an IC device assembly 2300 that may include components having one or more IC devices with stacked two-level backend memory in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of one or more IC devices with stacked two-level backend memory in accordance with any of the embodiments disclosed herein; e.g., any of the IC packages discussed below with reference to the IC device assembly 2300 may take the form of any of the embodiments of the IC package 2200 discussed above with reference to FIG. 13 (e.g., may include one or more IC devices with stacked two-level backend memory provided on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 14 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 14), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 11B), an IC device (e.g., the IC device 2100 of FIG. 12), or any other suitable component. In particular, the IC package 2320 may include one or more IC devices with stacked two-level backend memory as described herein. Although a single IC package 2320 is shown in FIG. 14, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 14, the IC package 2320 and the circuit board 2302 are attached to opposing sides of the interposer 2304; in other embodiments, the IC package 2320 and the circuit board 2302 may be attached to the same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as radio frequency (RF) devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 14 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

FIG. 15 is a block diagram of an example computing device 2400 that may include one or more components with one or more IC devices with stacked two-level backend memory in accordance with any of the embodiments disclosed herein. For example, any suitable ones of the components of the computing device 2400 may include a die (e.g., the die 2002 (FIG. 11B)) including stacked two-level backend memory in accordance with any of the embodiments disclosed herein. Any of the components of the computing device 2400 may include an IC device 2100 (FIG. 12) and/or an IC package 2200 (FIG. 13). Any of the components of the computing device 2400 may include an IC device assembly 2300 (FIG. 14).

A number of components are illustrated in FIG. 15 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC die.

Additionally, in various embodiments, the computing device 2400 may not include one or more of the components illustrated in FIG. 15, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory. The memory 2404 may include one or more IC devices with stacked two-level backend memory as described herein.

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 602.11 family), IEEE 602.16 standards (e.g., IEEE 602.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 602.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 602.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include an other output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

### SELECT EXAMPLES

The following paragraphs provide various examples of the embodiments disclosed herein.

Example 1 provides an IC device that includes a FEOL layer, including frontend transistors; a first memory layer, including a first memory cell that includes an access transistor and a capacitor, coupled to the access transistor; and a second memory layer, including a second memory cell that includes a selector device and a storage element coupled to the selector device, where the first memory layer is between the FEOL layer and the second memory layer.

Example 2 provides the IC device according to example 1, where the first memory layer and the second memory layer are parts of a BEOL layer of the IC device.

Example 3 provides the IC device according to examples 1 or 2, where at least one of the frontend transistors is coupled to the first memory cell, e.g., to be a part of a peripheral circuit for a memory array of first memory cells, provided in the first memory layer, and at least one of the frontend transistors is coupled to the second memory cell, e.g., to be a part of a peripheral circuit for a memory array of second memory cells, provided in the second memory layer.

Example 4 provides the IC device according to any one of the preceding examples, where at least one of the frontend transistors is coupled to the first memory cell and to the second memory cell, e.g., to be a part of a peripheral circuit shared between a memory array of first memory cells, provided in the first memory layer, and a memory array of second memory cells, provided in the second memory layer.

Example 5 provides the IC device according to any one of the preceding examples, where the first memory cell or the second memory cell includes a semiconductor material with an average grain size greater than 1 millimeter. For example, the access transistor of the first memory cell may include such a substantially single-crystalline semiconductor material in a channel region of the access transistor.

Example 6 provides the IC device according to any one of the preceding examples, where the first memory cell or the second memory cell includes a semiconductor material with an average grain size between 0.5 millimeter and 1 millimeter. For example, the access transistor of the first memory cell may include such a substantially polycrystalline semiconductor material in a channel region of the access transistor.

Example 7 provides the IC device according to any one of the preceding examples, where the first memory cell or the second memory cell includes a semiconductor material with an average grain size smaller than 0.5 millimeter. For example, the access transistor of the first memory cell may include such a substantially polymorphous semiconductor material in a channel region of the access transistor.

Example 8 provides the IC device according to any one of the preceding examples, where the access transistor is a TFT.

Example 9 provides the IC device according to any one of the preceding examples, where the selector device includes a first electrode, a second electrode, and a selector material between the first electrode and the second electrode, and the selector material includes a chalcogenide.

Example 10 provides the IC device according to example 9, where the selector device further includes a getter layer between the second electrode and the selector material.

Example 11 provides the IC device according to example 10, where the getter layer includes tantalum, titanium, hafnium, aluminum, or chromium.

Example 12 provides the IC device according to example 11, where the getter layer further includes nitrogen (e.g., the getter layer includes a nitride).

Example 13 provides the IC device according to any one of the preceding examples, where the storage element is a RRAM device, a PCM device, a metal filament memory device, or a MRAM device.

Example 14 provides the IC device according to any one of the preceding examples, further including a first BL, coupled to a first terminal of the first memory cell, a first WL, coupled to a second terminal of the first memory cell, a second BL, coupled to a first terminal of the second memory cell, and a second WL, coupled to a second terminal of the second memory cell.

Example 15 provides the IC device according to any one of the preceding examples, where the first memory cell is one of a plurality of first memory cells of a memory array in the first memory layer, and the second memory cell is one of a plurality of second memory cells of a memory array in the second memory layer.

Example 16 provides the IC device according to example 15, where the memory array in the first memory layer is a DRAM array, and the memory array in the second memory layer is a cross-point memory array.

Example 17 provides an IC package that includes an IC device according to any one of the preceding examples; and a further IC component, coupled to the IC device. The IC device may include, for example, an FEOL layer, including frontend transistors; a first memory layer, including first memory cells; and a second memory layer, including second memory cells, where the first memory cells are memory cells of a first type, the second memory cells are memory cells of a second type, and the first memory layer is between the FEOL layer and the second memory layer.

Example 18 provides the IC package according to example 17, where the first type and the second type are different ones of DRAM, cross-point memory, NAND memory, SRAM, and resistive switching memory.

Example 19 provides the IC package according to examples 17 or 18, where the first component or the second component includes one of a package substrate, an interposer, or a further IC die.

Example 20 provides the IC package according to any one of examples 15-19, where the IC device includes, or is a part of, at least one of a memory device, a computing device, a wearable device, a handheld electronic device, and a wireless communications device.

Example 21 provides an electronic device that includes a carrier substrate; and one or more of the IC device according to any one of the preceding examples and the IC package according to any one of the preceding examples, coupled to the carrier substrate.

Example 22 provides the electronic device according to example 21, where the carrier substrate is a motherboard.

Example 23 provides the electronic device according to example 21, where the carrier substrate is a PCB.

Example 24 provides the electronic device according to any one of examples 21-23, where the electronic device is a wearable electronic device (e.g., a smart watch) or handheld electronic device (e.g., a mobile phone).

Example 25 provides the electronic device according to any one of examples 21-24, where the electronic device further includes one or more communication chips and an antenna.

Example 26 provides the electronic device according to any one of examples 21-25, where the electronic device is an RF transceiver.

Example 27 provides the electronic device according to any one of examples 21-25, where the electronic device is one of a switch, a power amplifier, a low-noise amplifier, a filter, a filter bank, a duplexer, an upconverter, or a downconverter of an RF communications device, e.g., of an RF transceiver.

Example 28 provides the electronic device according to any one of examples 21-25, where the electronic device is a computing device.

Example 29 provides the electronic device according to any one of examples 21-28, where the electronic device is included in a base station of a wireless communication system.

Example 30 provides the electronic device according to any one of examples 21-28, where the electronic device is included in a user equipment device (i.e., a mobile device) of a wireless communication system.

Example 31 provides a method of fabricating an IC device. The method includes fabricating a frontend layer over a support structure, the frontend layer including frontend transistors; fabricating a first memory layer over the frontend layer, the first memory layer including memory cells of a first memory type; and fabricating a second memory layer over the first memory layer, the second memory layer including memory cells of a second memory type, where a plurality of the frontend transistors is coupled to one or more memory cells of the first memory type and one or more memory cells of the second memory type.

Example 32 provides the method according to example 31, where the support structure includes a semiconductor material, where a channel region of an individual one of the frontend transistors is a portion of the semiconductor material, and the method further includes performing a back-side reveal by removing at least a portion of the support structure to expose at least portions of the frontend layer, and fabricating a back-side interconnect structure, including back-side interconnects, over the exposed frontend layer, where at least one of the back-side interconnects is electrically coupled to one or more memory cells of the first memory type and one or more memory cells of the second memory type.

Example 33 provides the method according to example 32, further including fabricating a front-side interconnect structure, including front-side interconnects, over the second memory layer, where at least one of the front-side interconnects is electrically coupled to one or more memory cells of the first memory type and one or more memory cells of the second memory type.

Example 34 provides the method according to any one of examples 31-33, where the first type and the second type are different ones of DRAM, cross-point memory, NAND memory, SRAM, and resistive switching memory.

Example 35 provides the method according to any one of examples 31-34, further including processes for forming the IC device according to any one of the preceding examples (e.g., for forming the IC device according to any one of examples 1-16).

Example 36 provides the method according to any one of examples 31-35, further including processes for forming the IC package according to any one of the preceding examples (e.g., for forming the IC package according to any one of examples 17-20).

Example 37 provides the method according to any one of examples 31-36, further including processes for forming the electronic device according to any one of the preceding examples (e.g., for forming the electronic device according to any one of examples 21-30).

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a front end of line (FEOL) layer, comprising frontend transistors;
a first memory layer, comprising a first memory cell that includes an access transistor and a capacitor, coupled to the access transistor; and
a second memory layer, comprising a second memory cell that includes a selector device and a storage element coupled to the selector device,
wherein the first memory layer is between the FEOL layer and the second memory layer.

2. The IC device according to claim 1, wherein the first memory layer and the second memory layer are parts of a back end of line (BEOL) layer of the IC device.

3. The IC device according to claim 1, wherein at least one of the frontend transistors is coupled to the first memory cell and at least one of the frontend transistors is coupled to the second memory cell.

4. The IC device according to claim 1, wherein at least one of the frontend transistors is coupled to the first memory cell and to the second memory cell.

5. The IC device according to claim 1, wherein the first memory cell or the second memory cell includes a semiconductor material with an average grain size greater than 1 millimeter.

6. The IC device according to claim 1, wherein the first memory cell or the second memory cell includes a semiconductor material with an average grain size between 0.5 millimeter and 1 millimeter.

7. The IC device according to claim 1, wherein the first memory cell or the second memory cell includes a semiconductor material with an average grain size smaller than 0.5 millimeter.

8. The IC device according to claim 1, wherein the access transistor is a thin-film transistor.

9. The IC device according to claim 1, wherein:
the selector device includes a first electrode, a second electrode, and a selector material between the first electrode and the second electrode, and
the selector material includes a chalcogenide.

10. The IC device according to claim 9, wherein the selector device further includes a getter layer between the second electrode and the selector material.

11. The IC device according to claim 10, wherein the getter layer includes tantalum, titanium, hafnium, aluminum, or chromium.

12. The IC device according to claim 11, wherein the getter layer further includes nitrogen.

13. The IC device according to claim 1, wherein the storage element is a resistive random-access memory (RRAM) device, a phase change memory (PCM) device, a metal filament memory device, or a magnetoresistive random-access memory (MRAM) device.

14. The IC device according to claim 1, further comprising:
a first bit-line, coupled to a first terminal of the first memory cell,
a first word-line, coupled to a second terminal of the first memory cell,
a second bit-line, coupled to a first terminal of the second memory cell, and
a second word-line, coupled to a second terminal of the second memory cell.

15. The IC device according to claim 1, wherein:
the first memory cell is one of a plurality of first memory cells of a memory array in the first memory layer,
the second memory cell is one of a plurality of second memory cells of a memory array in the second memory layer,
the memory array in the first memory layer is a dynamic random-access memory array, and
the memory array in the second memory layer is a cross-point memory array.

16. An integrated circuit (IC) package, comprising:
an IC device; and
a further IC component, coupled to the IC device,
wherein the IC device includes:
a front end of line (FEOL) layer, comprising frontend transistors;
a first memory layer, comprising first memory cells; and
a second memory layer, comprising second memory cells,
wherein:
the first memory cells are memory cells of a first type,
the second memory cells are memory cells of a second type, and
the first memory layer is between the FEOL layer and the second memory layer.

17. The IC package according to claim 16, wherein the first type and the second type are different ones of dynamic random-access memory (DRAM), cross-point memory, NAND memory, static random-access memory (SRAM), and resistive switching memory.

18. A method of fabricating an integrated circuit (IC) device, the method comprising:
fabricating a frontend layer over a support structure, the frontend layer comprising frontend transistors;
fabricating a first memory layer over the frontend layer, the first memory layer including memory cells of a first memory type; and
fabricating a second memory layer over the first memory layer, the second memory layer including memory cells of a second memory type,
wherein a plurality of the frontend transistors is coupled to one or more memory cells of the first memory type and one or more memory cells of the second memory type.

19. The method according to claim 18, wherein:
the support structure includes a semiconductor material, where a channel region of an individual one of the frontend transistors is a portion of the semiconductor material, and
the method further includes:
removing at least a portion of the support structure to expose at least portions of the frontend layer, and
fabricating a back-side interconnect structure, comprising back-side interconnects, over the exposed frontend layer,
wherein at least one of the back-side interconnects is coupled to one or more memory cells of the first memory type and one or more memory cells of the second memory type.

20. The method according to claim 19, further comprising:
fabricating a front-side interconnect structure, comprising front-side interconnects, over the second memory layer,
wherein at least one of the front-side interconnects is coupled to one or more memory cells of the first memory type and one or more memory cells of the second memory type.
